(19) United States
(12) Patent Application Publication
(10) Pub. No.: US 2026/0105941 A1
(43) Pub. Date: Apr. 16, 2026

(54) SEMICONDUCTOR MEMORY DEVICE AND METHOD FOR MANUFACTURING THE SAME

(71) Applicant: Samsung Electronics Co., Ltd., Suwon-si (KR)

(72) Inventors: Hyun Ah ROH, Suwon-si (KR); Hyun Ji KWON, Suwon-si (KR); Song Eun BEACK, Suwon-si (KR); Seung Young SEO, Suwon-si (KR); Hyun Min CHO, Suwon-si (KR); Taek Yong KIM, Suwon-si (KR); Tae Jin PARK, Suwon-si (KR)

(21) Appl. No.: 19/336,802

(22) Filed: Sep. 23, 2025

(30) Foreign Application Priority Data
Oct. 14, 2024 (KR) 10-2024-0139491

(51) Int. Cl. G11C 5/06; H10B 12/00

(52) U.S. Cl. CPC G11C 5/063; H10B 12/02; H10B 12/315; H10B 12/482

(57) ABSTRACT

A semiconductor memory device including a vertical channel transistor (VCT) and a method for manufacturing the same are provided. The semiconductor memory device comprising a first region and a second region arranged along a first direction, the semiconductor memory device comprising an active pattern in the first region, a conductive line on a lower surface of the active pattern, the conductive line connected to the active pattern and extending in the first direction across the first region and the second region, a spacer film extending along a side surface and a lower surface of the conductive line, the spacer film including a first portion in the first region and a second portion in the second region, a shield conductive film covering the first portion of the spacer film and not covering the second portion of the spacer film, a gate electrode adjacent to a side surface of the active pattern, the gate electrode extending in a second direction crossing the first direction, and a data storage structure on an upper surface of the active pattern, the data storage structure connected to the active pattern, wherein a thickness of the second portion is smaller than a thickness of the first portion, or the second portion of the spacer film does not extend along the lower surface of the conductive line.

### CROSS-REFERENCE TO RELATED APPLICATION

This application claims priority from Korean Patent Application No. 10-2024-0139491 filed on Oct. 14, 2024 in the Korean Intellectual Property Office, and all the benefits accruing therefrom under 35 U.S.C. 119, the contents of which are hereby incorporated by reference in its entirety.

### BACKGROUND

### Technical Field

The present disclosure relates to a semiconductor memory device and a method for manufacturing the same. More specifically, the present disclosure relates to a semiconductor memory device including a vertical channel transistor (VCT) and a method for manufacturing the same.

### Description of Related Art

In order to meet excellent performance and low price demanded by a consumer, semiconductor memory devices with improved an integration level continue to be developed. Since the integration level of the semiconductor memory device is an important factor in determining a price of the product, a high integration level is particularly important.

In a two-dimensional or planar semiconductor memory device, the integration level is mainly determined based on an area occupied by a unit memory cell, and therefore is greatly affected by a level of fine pattern formation technology. However, expensive equipment is required for pattern miniaturization. Thus, the integration level of the two-dimensional semiconductor memory device is increasing but is still limited. Accordingly, a semiconductor memory device including a vertical channel transistor in which a channel extends in a vertical direction is developed.

### SUMMARY

A technical purpose to be achieved by the present disclosure is to provide a semiconductor memory device with improved performance and productivity.

Another technical purpose to be achieved by the present disclosure is to provide a method for manufacturing a semiconductor memory device with improved performance and productivity.

The technical purposes of the present disclosure are not limited to the technical purposes as mentioned above, and other technical purposes as not mentioned may be clearly understood by those skilled in the art from descriptions as set forth below.

According to an aspect of the present inventive concept, there is provided a semiconductor memory device comprising a first region and a second region arranged along a first direction, the semiconductor memory device comprising an active pattern in the first region, a conductive line on a lower surface of the active pattern, the conductive line connected with the active pattern and extending in the first direction across the first region and the second region, a spacer film extending along a side surface and a lower surface of the conductive line, the spacer film including a first portion in the first region and a second portion in the second region, a shield conductive film extending below the first portion of the spacer film and not extending below the second portion of the spacer film, a gate electrode adjacent to a side surface of the active pattern, the gate electrode extending in a second direction crossing the first direction, and a data storage structure on an upper surface of the active pattern, the data storage structure connected with the active pattern, wherein a thickness of the second portion is smaller than a thickness of the first portion, or the first portion of the spacer film extends along the lower surface of the conductive line and the second portion of the spacer film does not extend along the lower surface of the conductive line.

According to an aspect of the present inventive concept, there is provided a semiconductor memory device comprising a first region and a second region arranged along a first direction, the semiconductor memory device comprising a first active pattern and a second active pattern in the first region, the first active pattern and the second active pattern spaced apart from each other in a second direction intersecting the first direction, a first conductive line on a lower surface of the first active pattern, the first conductive line connected with the first active pattern and extending in the first direction across the first region and the second region, a second conductive line on a lower surface of the second active pattern, the second conductive line connected with the second active pattern and extending in the first direction across the first region and the second region, a shield conductive film interposed between the first conductive line in the first region and the second conductive line in the first region, a filling insulating film interposed between the first conductive line in the second region and the second conductive line in the second region, a spacer film including a first portion in the first region that is interposed between the first conductive line and the shield conductive film, and a second portion in the second region that is interposed between the first conductive line and the filling insulating film, a gate electrode adjacent to a side surface of the first active pattern and adjacent to a side surface of the second active pattern, the gate electrode extending in the second direction, and a first data storage structure on an upper surface of the first active pattern and connected to the first active pattern, and a second data storage structure on an upper surface of the second active pattern and connected to the second active pattern, wherein a thickness of the second portion of the spacer film is smaller than a thickness of the first portion of the spacer film, or the first portion of the spacer film extends along lower surfaces of the first conductive line and the second conductive line and the second portion of the spacer film does not extend along the lower surfaces of the first conductive line and the second conductive line.

According to an aspect of the present inventive concept, there is provided a semiconductor memory device comprising a first region and a second region arranged along a first direction, the semiconductor memory device comprising an active pattern in the first region, a conductive line on a lower surface of the active pattern, the conductive line connected with the active pattern, the conductive line extending in the first direction, and the conductive line having an end in the second region, a capping film extending along a lower surface of the conductive line, a spacer film extending along a side surface of the conductive line and a side surface and a lower surface of the capping film, the spacer film including a first portion in the first region and a second portion in the second region, a shield conductive film extending below the first portion of the spacer film and not extending below the second portion of the spacer film, a gate electrode adjacent to a side surface of the active pattern, the gate electrode extending in a second direction crossing the first direction, a data storage structure on an upper surface of the active pattern, the data storage structure being connected to the active pattern, a first contact in the first region, the first contact connected with a lower surface of the shield conductive film, and a second contact in the second region, the second contact connected with the lower surface of the conductive line, wherein the second portion of the spacer film extends along a lower surface of the capping film in the first region and does not extend along a lower surface of the capping film in the second region.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is an example layout diagram for illustrating a semiconductor memory device according to some embodiments.

FIG. 2 is a cross-sectional view taken along a line A-A of FIG. 1.

FIG. 3 is an enlarged view for illustrating an R1 region of FIG. 2.

FIG. 4 is a cross-sectional view taken along a line B-B of FIG. 1.

FIG. 5 is an enlarged view for illustrating an R2 region of FIG. 4.

FIG. 6 is a cross-sectional view taken along lines C1-C1 and C2-C2 of FIG. 1.

FIGS. 7A to 7E are various enlarged diagrams for illustrating an R3 region and an R4 region of FIG. 6.

FIGS. 8 and 9 are cross-sectional views for illustrating a semiconductor memory device according to some embodiments. FIG. 8 is a cross-sectional view taken along a line A-A of FIG. 1. FIG. 9 is a cross-sectional view taken along a line B-B of FIG. 1.

FIG. 10 is a cross-sectional view for illustrating a semiconductor memory device according to some embodiments.

FIG. 11 is a cross-sectional view for illustrating a semiconductor memory device according to some embodiments.

FIG. 12 is a cross-sectional view for illustrating a semiconductor memory device according to some embodiments.

FIGS. 13 to 48 are diagrams of intermediate structures corresponding to intermediate steps of a method for manufacturing a semiconductor memory device according to some embodiments.

### DETAILED DESCRIPTIONS

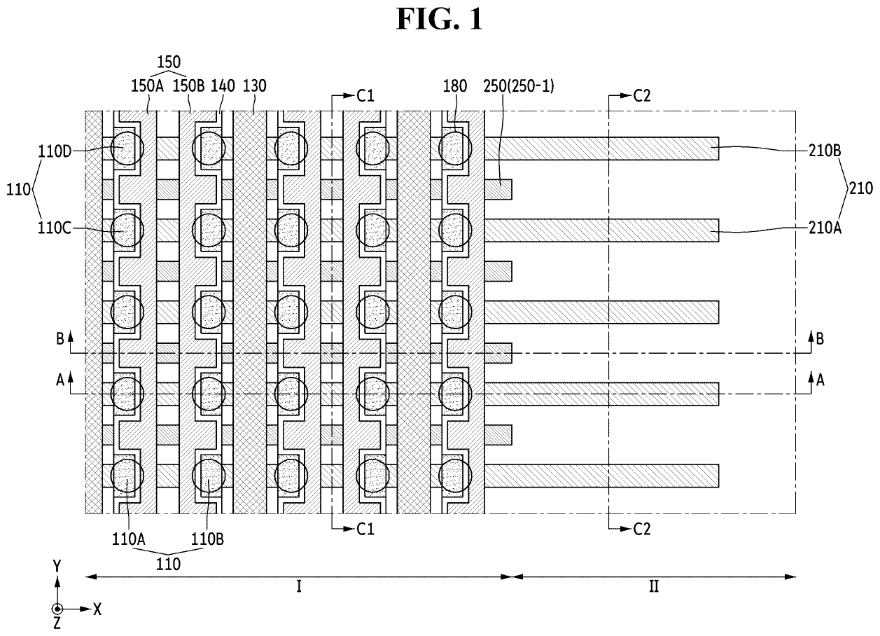

Hereinafter, with reference to FIGS. 1 to 12, a semiconductor memory device according to some embodiments is described.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Items described in the singular herein may be provided in plural, as can be seen, for example, in the drawings. Thus, the description of a single item that is provided in plural should be understood to be applicable to the remaining plurality of items unless context indicates otherwise.

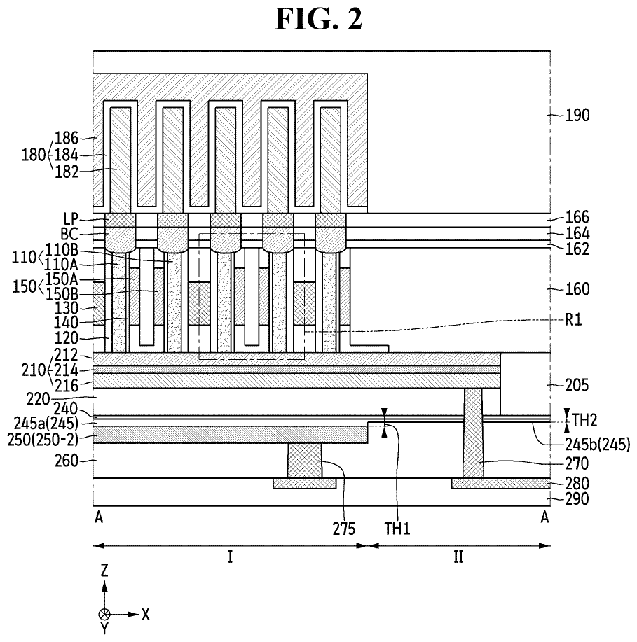

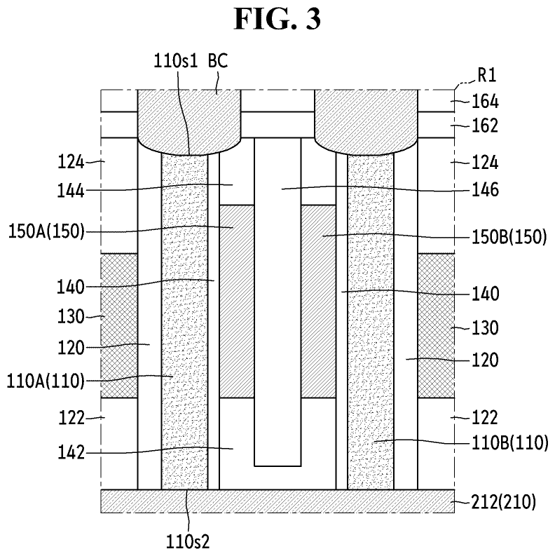

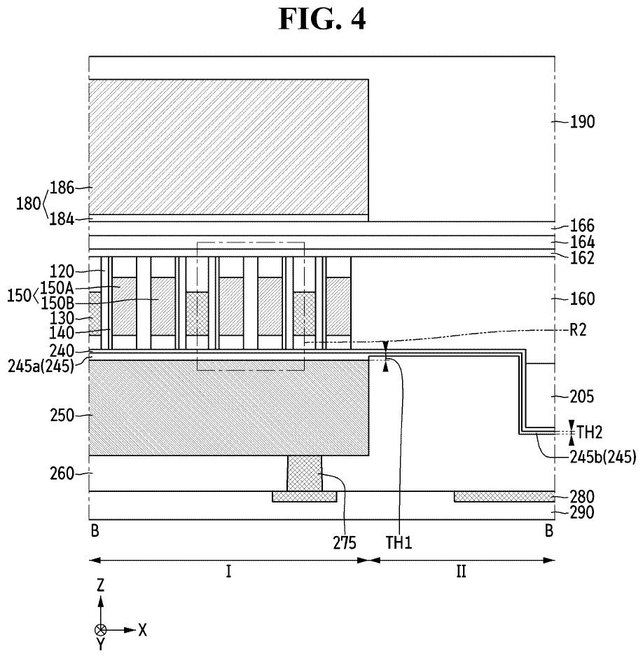

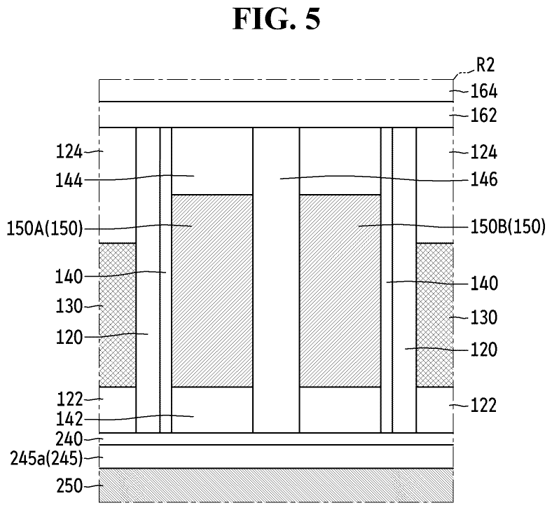

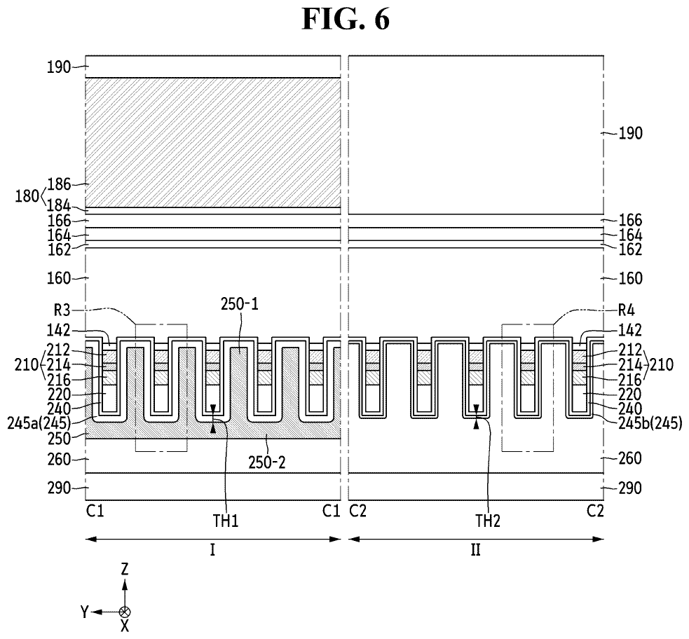

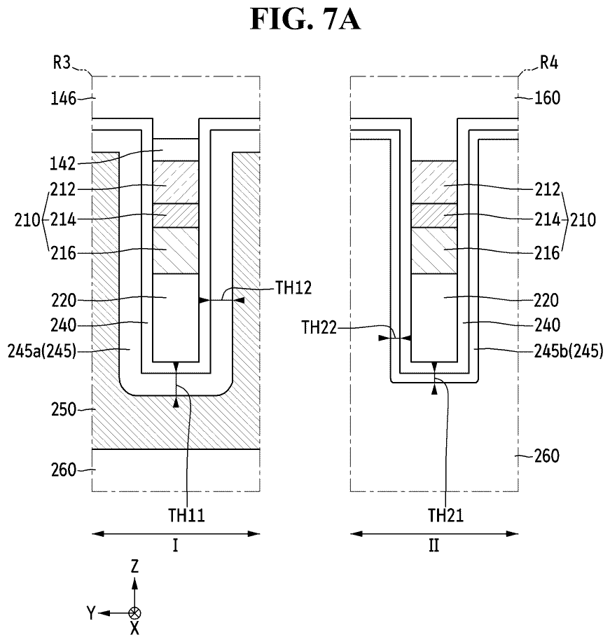

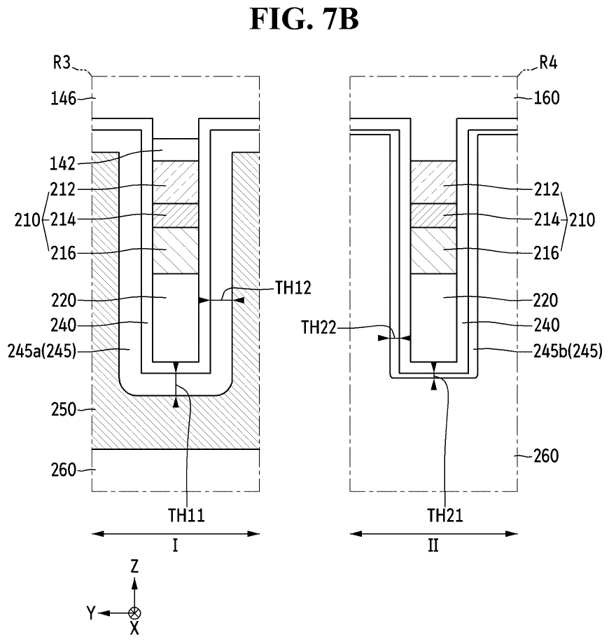

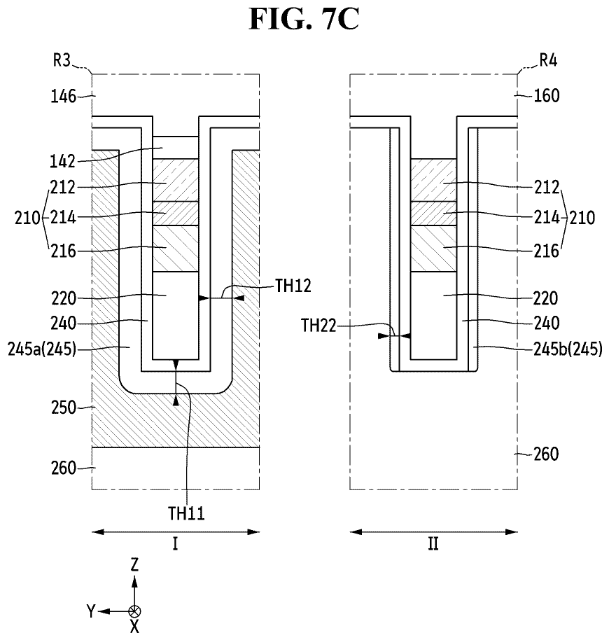

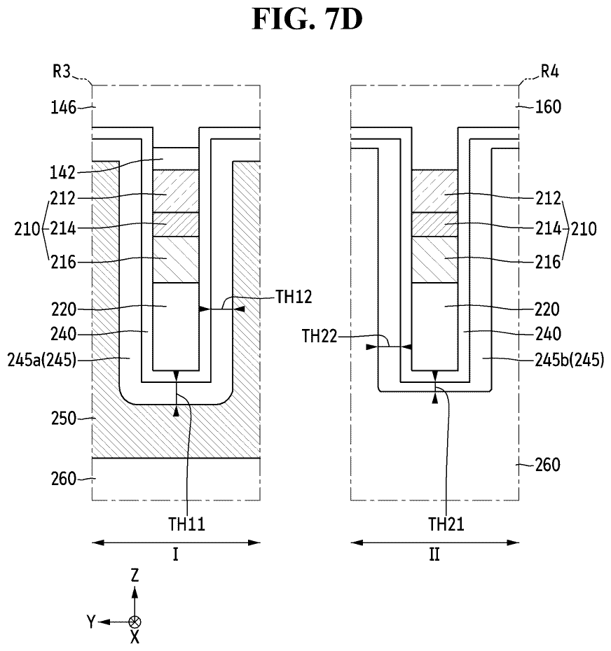

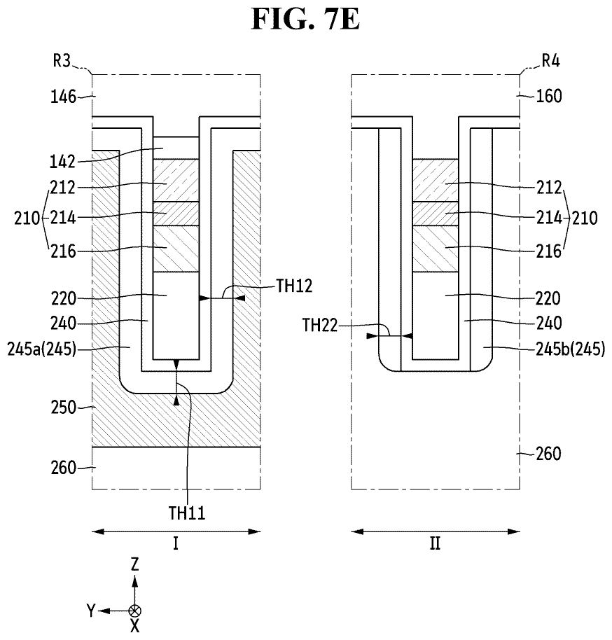

FIG. 1 is an example layout diagram for illustrating a semiconductor memory device according to some embodiments. FIG. 2 is a cross-sectional view taken along a line A-A of FIG. 1. FIG. 3 is an enlarged view for illustrating an R1 region of FIG. 2. FIG. 4 is a cross-sectional view taken along a line B-B of FIG. 1. FIG. 5 is an enlarged view for illustrating an R2 region of FIG. 4. FIG. 6 is a cross-sectional view taken along lines C1-C1 and C2-C2 of FIG. 1. FIGS. 7A to 7E are various enlarged diagrams for illustrating an R3 region and an R4 region of FIG. 6.

Referring to FIGS. 1 to 7A, a semiconductor memory device according to some embodiments includes a first region I and a second region II.

The first region I and the second region II may be arranged along a first direction X. The first region I may be a memory cell array region where memory cells are disposed. The second region II may be an edge region disposed at an edge of the memory cell array region (e.g., first region I). For example, the second region II may be an edge region adjacent to a core/peripheral region formed around the memory cell array region and thus second region II may be disposed between the first region I and the core/peripheral region (e.g., a portion of the core/peripheral region to the right of second region II in FIG. 1 (not shown)).

According to some embodiments, the semiconductor memory device includes active patterns 110, gate electrodes 150, a gate dielectric film 140, back gate electrodes 130, a back gate dielectric film 120, contact patterns BC, landing patterns LP, data storage structures 180, an upper insulating film 190, conductive lines 210, a capping film 220, a liner film 240, a spacer film 245, a shield conductive film 250, a filling insulating film 260, first contacts 270, second contacts 275, and first wiring structures 280.

The active patterns 110 may be disposed in the first region I. The active patterns 110 may be arranged two-dimensionally along a horizontal plane (e.g., extending in the X and Y direction). For example, the active patterns 110 may be arranged in a matrix form along the first direction X and a second direction Y that intersect each other.

Each of the active patterns 110 may extend in a vertical direction. For example, each of the active patterns 110 may extend in a third direction Z that intersects the first direction X and the second direction Y. A length by which each of the active patterns 110 extends in the third direction Z (i.e., a height of the active patterns 110) may be greater than a width (e.g., a width in the first direction X and/or a width in the second direction Y) of each of the active patterns 110. The height of each of the active patterns 110 may be in a range of about 2 to about 10 times of the width of each of the active patterns 110. However, embodiments of the present disclosure are not limited thereto. Each of the active patterns 110 may form a channel region of a corresponding vertical channel transistor (VCT). The vertical channel transistor may refer to transistor in having a channel length (of the channel region of its channel layer) that extends in the vertical direction (e.g., the third direction Z). Each vertical channel transistor may also include a gate electrode 150 that is adjacent to its active pattern 110, a first source/drain formed at the top portion of its active pattern 110 and a second source/drain formed at the bottom portion of its active pattern 110. A unit memory cell may be formed with the combination a vertical channel transistor and a data storage structure 180 connected together as described herein.

Each of the active patterns 110 may include a semiconductor material. For example, each of the active patterns 110 may include silicon, silicon germanium, SGOI (silicon germanium on insulator), indium antimonide, lead telluride compound, indium arsenide, indium phosphide, gallium arsenide, or gallium antimonide. Each of the active patterns 110 may be formed of a single layer only or multiple layers made of semiconductor material. In some embodiments, each of the active patterns 110 may be formed of a crystalline (e.g., a single crystal) semiconductor material. In one example, each of the active patterns 110 may be crystalline silicon.

The gate electrodes 150 may be disposed on side surfaces of the active patterns 110. The gate electrodes 150 may extend adjacent to (and may at least partially surround) the active patterns 110. For example, the gate electrodes 150 may be spaced apart from each other in the first direction X and may extend lengthwise in the second direction Y. An item, layer, or portion of an item or layer described as extending “lengthwise” in a particular direction has a length in the particular direction and a width perpendicular to that direction, where the length is greater than the width. It should be understood that the width of a wiring is in a direction perpendicular to the extending direction of the wiring, where the extending direction is the path of the wiring (e.g., corresponding to the current path provided by the wiring). Each of the gate electrodes 150 may extend along a corresponding column of active patterns 110 arranged along the second direction Y. The gate electrodes 150 may be provided as word lines of the semiconductor memory device according to some embodiments.

Each of the gate electrodes 150 may include a conductive material, for example, at least one of doped polysilicon, a metal, a conductive metal nitride, a conductive metal silicide, a conductive metal oxide, or a combination thereof. For example, each of the gate electrodes 150 may include, but is not limited to, at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof.

The gate electrodes 150 may be spaced apart from the conductive lines 210 in the third direction Z. For example, as illustrated in FIG. 3, a first lower spacer pattern 142 may be formed between the gate electrodes 150 and the conductive lines 210. The gate electrodes 150 may be stacked on an upper surface of the first lower spacer pattern 142. The gate electrodes 150 may be spaced apart from the conductive lines 210 via the first lower spacer pattern 142.

The gate electrodes 150 may be spaced apart from an etch-stop film 162 in the third direction Z. For example, as shown in FIG. 3, a first upper spacer pattern 144 may be formed between the gate electrodes 150 and the etch-stop film 162. The first upper spacer pattern 144 may be stacked on upper surfaces of the gate electrodes 150. The gate electrodes 150 may be spaced apart from the etch-stop film 162 via the first upper spacer pattern 144.

Each of the first lower spacer pattern 142 and the first upper spacer pattern 144 may include an insulating material, for example, at least one of silicon oxide, silicon nitride, silicon oxynitride, silicon oxycarbonitride, or a combination thereof. However, embodiments of the present disclosure are not limited thereto. Each of the first lower spacer pattern 142 and the first upper spacer pattern 144 may be embodied as a single homogenous film made of one type of the insulating material, or may be embodied as a stack of several component films respectively made of several types of insulating materials.

In some embodiments, the gate electrodes 150 may include a first gate electrode 150A and a second gate electrode 150B that face each other in the first direction X. For example, the active patterns 110 may include a first active pattern 110A and a second active pattern 110B that are arranged adjacent to each other in the first direction X. The first gate electrode 150A and the second gate electrode 150B may be interposed between the first active pattern 110A and the second active pattern 110B. The first gate electrode 150A may be disposed adjacent to a side surface of the first active pattern 110A that faces the second active pattern 110B, and the second gate electrode 150B may be disposed adjacent to a side surface of the second active pattern 110B that faces the first active pattern 110A. The first gate electrode 150A may be provided as a word line of a unit memory cell including the first active pattern 110A, and the second gate electrode 150B may be provided as a word line of a unit memory cell including the second active pattern 110B.

The first gate electrode 150A and the second gate electrode 150B may be spaced apart from each other in the first direction X. For example, an isolation insulating film 146 may be formed between the first gate electrode 150A and the second gate electrode 150B. The isolation insulating film 146 may extend in the second direction Y to isolate the first gate electrode 150A and the second gate electrode 150B from each other.

The gate dielectric film 140 may be interposed between the active patterns 110 and the gate electrodes 150. For example, the gate dielectric film 140 may extend along a side surface of each of the active patterns 110. The gate electrodes 150 may be spaced apart from the side surfaces of the active patterns 110 via the gate dielectric film 140.

The gate dielectric film 140 may include, but is not limited to, at least one of silicon oxide, silicon oxynitride, and a high-k material having a higher dielectric constant than that of silicon oxide, or a combination thereof. The high-k material may include, but is not limited to, at least one of metal oxide or metal oxynitride, for example, HfO₂, HfSiO, HfSiON, HfTaO, HfTiO, HfZrO, ZrO₂, Al₂O₃, or a combination thereof.

The back gate electrodes 130 may be disposed adjacent to side surfaces of the active patterns 110. For example, the gate electrodes 150 may be spaced apart from each other in the first direction X and may extend lengthwise in the second direction Y. The active patterns 110 may be respectively interposed between neighboring ones of the gate electrodes 150 and the back gate electrodes 130. For example, the first active pattern 110A may be interposed between one of the back gate electrodes 130 and the first gate electrode 150A, and the second active pattern 110B may be interposed between another of the back gate electrodes 130 and the second gate electrode 150B. Portions of the back gate electrode adjacent active patterns 110 may correspond to back gates of the corresponding vertical channel transistor (formed with the corresponding active pattern). When the semiconductor memory device operates, a voltage may be provided to the back gate electrode 130 to control a threshold voltage of these vertical channel transistors, thereby reducing leakage current.

Each of the back gate electrodes 130 may include a conductive material, for example, at least one of doped polysilicon, a metal, a conductive metal nitride, a conductive metal silicide, a conductive metal oxide, or a combination thereof. For example, each of the back gate electrodes 130 may include, but is not limited to, at least one of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof.

The back gate electrodes 130 may be spaced apart from the conductive lines 210 in the third direction Z. For example, as illustrated in FIG. 3, a second lower spacer pattern 122 may be formed between the back gate electrodes 130 and the conductive lines 210. The back gate electrodes 130 may be stacked on an upper surface of the second lower spacer pattern 122. The back gate electrodes 130 may be spaced from the conductive lines 210 via the second lower spacer pattern 122.

The back gate electrodes 130 may be spaced from the etch-stop film 162 in the third direction Z. For example, as shown in FIG. 3, a second upper spacer pattern 124 may be formed between the back gate electrodes 130 and the etch-stop film 162. The second upper spacer pattern 124 may be stacked on upper surfaces of the back gate electrodes 130. The back gate electrodes 130 may be spaced from the etch-stop film 162 via the second upper spacer pattern 124.

Each of the second lower spacer pattern 122 and the second upper spacer pattern 124 may include an insulating material, for example, at least one of silicon oxide, silicon nitride, silicon oxynitride, silicon oxycarbonitride, or a combination thereof. However, embodiments of the present disclosure are not limited thereto. Each of the second lower spacer pattern 122 and the second upper spacer pattern 124 may be embodied as a single homogenous film made of one type of insulating material, or may be embodied as a stack of several component films respectively made of several types of the insulating materials.

The back gate dielectric film 120 may be interposed between the active patterns 110 and the back gate electrodes 130. For example, the back gate dielectric film 120 may extend along the side surface of each of the active patterns 110. The back gate electrodes 130 may be spaced from the side surfaces of the active patterns 110 via the back gate dielectric film 120.

The back gate dielectric film 120 may include, but is not limited to, at least one of silicon oxide, silicon oxynitride, and a high-k material having a higher dielectric constant than that of silicon oxide, or a combination thereof. The high-k material may include, but is not limited to, at least one of metal oxide or metal oxynitride, for example, HfO₂, HfSiO, HfSiON, HfTaO, HfTiO, HfZrO, ZrO₂, Al₂O₃, or a combination thereof.

The active patterns 110, the gate electrodes 150, the gate dielectric film 140, the back gate electrodes 130, and the back gate dielectric film 120 may be formed within the first interlayer insulating film 160. For example, the first interlayer insulating film 160 may fill a space on an outer side surface of each of the active patterns 110, the gate electrodes 150, and the back gate electrodes 130. The first interlayer insulating film 160 may include, but is not limited to, silicon oxide, silicon oxynitride, and a low-k material having a lower dielectric constant than that of silicon oxide, or a combination thereof.

A contact pattern BC may be disposed on an upper surface (e.g., 110s1 of FIG. 3) of each of the active patterns 110. A corresponding contact pattern BC may be in contact with each of the active patterns 110. For example, the etch-stop film 162 and the second interlayer insulating film 164 may be sequentially stacked on an upper surface of the first interlayer insulating film 160. A contact pattern BC may extend through the etch-stop film 162 and the second interlayer insulating film 164 so as to be in contact with the upper surface 110s1 of a corresponding active pattern 110.

The contact patterns BC may include a conductive material, for example, at least one of doped polysilicon, a conductive metal nitride, a conductive metal silicon nitride, a metal carbonitride, a conductive metal silicide, a conductive metal oxide, a two-dimensional material, a metal, or a combination thereof. However, embodiments of the present disclosure are not limited thereto.

A landing pad LP may be disposed on an upper surface of each of the contact patterns BC. The landing pad LP may be in contact with the contact pattern BC. For example, a third interlayer insulating film 166 may be stacked on an upper surface of the second interlayer insulating film 164. A landing pad LP may extend through the third interlayer insulating film 166 so as to be in contact with an upper surface of the corresponding contact pattern BC.

The landing pads LP may include a conductive material, for example, at least one of doped polysilicon, a conductive metal nitride, a conductive metal silicon nitride, a metal carbonitride, a conductive metal silicide, a conductive metal oxide, a two-dimensional material, a metal, or a combination thereof. However, embodiments of the present disclosure are not limited thereto.

A data storage structure 180 may be disposed on an upper surface of each landing pad LP. The data storage structure 180 may be in contact with the landing pad LP. The data storage structure 180 may be in electrical contact with the active patterns 110 via the contact pattern BC and the landing pad LP.

The data storage structures 180 may be controlled via the conductive lines 210 (which may be bit lines) and the gate electrodes 150 (which may be word lines) to store data in the memory cells formed in the first region I. In some embodiments, each data storage structure 180 may be a capacitor. For example, the data storage structure 180 may include a lower electrode 182, a capacitor dielectric film 184, and an upper electrode 186 sequentially stacked on a corresponding landing pad LP. The data storage structure 180 may store charges in the capacitor dielectric film 184 under a potential difference between an electrical potential of the lower electrode 182 and an electrical potential of the upper electrode 186. It should be appreciated that FIG. 4 illustrates the data storage structure 180 (including lower electrode 182, dielectric film 184 and upper electrode 186) is shown above shield conductive film 250 which may represent the data storage structures 180 associated with a vertical transistors formed with neighboring gate electrodes 150. In some embodiments, the lower electrodes 182 (and/or the entire data storage structure 180) may be separated in the Y direction to provide discrete electrical nodes (e.g., discrete lower electrodes 182), each dedicated to a corresponding vertical transistor (e.g., connected to a neighboring gate electrode 150) such a that each vertical transistor is connected to a corresponding dedicated and discrete data storage structure 180 (e.g., a discrete capacitor).

Each of the lower electrode 182 and the upper electrode 186 may include, but is not limited to, for example, doped polysilicon, a metal, or a metal nitride. Furthermore, the capacitor dielectric film 184 may include, but is not limited to, silicon oxide or a high-k material, for example.

A capacitor is one example of the data storage structure 180 and the invention is not limited thereto. For example, the data storage structure may be a programmable resistive material(s) and form a phase-change random access memory (PRAM) memory cell, magnetoresistive random access memory (MRAM) memory cell, ferroelectric random access memory (FeRAM) memory cell, or a resistive random access memory (RRAM) memory cell.

The upper insulating film 190 may be formed on the third interlayer insulating film 166 and the data storage structure 180. The upper insulating film 190 may cover the third interlayer insulating film 166 and the data storage structure 180.

The conductive lines 210 may be disposed under the active patterns 110, the gate electrodes 150, the gate dielectric film 140, the back gate electrodes 130, the back gate dielectric film 120, and the first interlayer insulating film 160. The conductive lines 210 may intersect the gate electrodes 150. For example, the conductive lines 210 may be spaced apart from each other in the second direction Y and may extend lengthwise in the first direction X. The conductive lines 210 may be in contact with lower surfaces (e.g., 110s2 in FIG. 3) of the active patterns 110. Each of the conductive lines 210 may be commonly connected to a corresponding row of active patterns 110 arranged along the first direction X. The conductive lines 210 may be provided as bit lines of the semiconductor memory device according to some embodiments.

The conductive lines 210 may extend across the first region I and the second region II. Each of the conductive lines 210 may have an end in the second region II that terminates the conductive line 210. For example, a fourth interlayer insulating film 205 may be formed in the second region II. The fourth interlayer insulating film 205 may define an end of each of the conductive lines 210 in the first direction X (e.g., ends of the conductive lines 210 may terminate at a side surface of the fourth interlayer insulating film 205).

In some embodiments, each of the conductive lines 210 may include a first conductive film 131, a second conductive film 132, and a third conductive film 133 sequentially stacked on the lower surface (e.g., 110s2 of FIG. 3) of the active patterns 110. Each of the first conductive film 131, the second conductive film 132, and the third conductive film 133 may include a conductive material, for example, at least one of polysilicon, TiN, TiSiN, tungsten, tungsten silicide, or a combination thereof. However, embodiments of the present disclosure are not limited thereto. In one example, the first conductive film 131 may include a polysilicon film (poly-Si film), the second conductive film 132 may include a TiSiN film, and the third conductive film 133 may include a tungsten film (W film).

The capping film 220 may extend along lower surfaces of the conductive lines 210. The capping film 220 may extend in the first direction X. The capping film 220 may include an insulating material, for example, at least one of silicon oxide, silicon nitride, silicon oxynitride, silicon oxycarbonitride, and combinations thereof. However, embodiments of the present disclosure are not limited thereto. In one example, the capping film 220 may include a silicon nitride film.

The liner film 240 may be formed under the first interlayer insulating film 160, the conductive lines 210, and the capping film 220. For example, the liner film 240 may extend conformally along and on side surfaces of the conductive lines 210, and a side surface and a lower surface of the capping film 220. In some embodiments, a vertical level of the uppermost surface of the liner film 240 may be higher than a vertical level of each of the lowermost surface of the first lower spacer pattern 142 and the lowermost surface of the second lower spacer pattern 122. A portion of the liner film 240 of the first region I may further extend along a lower surface of the isolation insulating film 146, a lower surface of the first lower spacer pattern 142, and a lower surface of the second lower spacer pattern 122. The portion of the liner film 240 of the first region I may further extend along the lower surface of the first interlayer insulating film 160. A portion of the liner film 240 of the second region II may further extend along the lower surface of the first interlayer insulating film 160.

The liner film 240 may include an insulating material, for example, at least one of silicon oxide, silicon nitride, silicon oxynitride, silicon carbonitride, and combinations thereof. However, embodiments of the present disclosure are not limited thereto. In one example, the liner film 240 may include a silicon nitride film.

The spacer film 245 may be formed under the liner film 240. For example, the spacer film 245 may extend conformally along and on a side surface and a lower surface of the liner film 240.

The spacer film 245 may include a first portion 245a in the first region I and a second portion 245b in the second region II. The first portion 245a of the spacer film 245 may extend along the portion of the liner film 240 of the first region I, and the second portion 245b of the spacer film 245 may extend along the portion of the liner film 240 of the second region II.

The spacer film 245 may include an insulating material, for example, at least one of silicon oxide, silicon nitride, silicon oxynitride, silicon oxycarbonitride, and combinations thereof. However, embodiments of the present disclosure are not limited thereto. In one example, the spacer film 245 may include a silicon oxide film.

In some embodiments, a thickness TH2 of the second portion 245b of the spacer film 245 may be smaller than a thickness TH1 of the first portion 245a of the spacer film 245. For example, the thickness TH1 of the first portion 245a may be in a range of about 45 Å to about 55 Å, and the thickness TH2 of the second portion 245b may be in a range of about 35 Å to about 45 Å. The thickness of a layer may refer to the dimension in the direction perpendicular to the surface of the layer. The direction perpendicular to the surface may refer to its average orientation and not include minor unintentional deviations (e.g., pits) that may be formed during a manufacturing process

A difference between the thickness TH1 of the first portion 245a and the thickness TH2 of the second portion 245b may be, for example, in a range of about 5 Å to about 15 Å.

In some embodiments, as illustrated in FIG. 7A, the first portion 245a on the lower surface of the liner film 240 may have the first thickness TH11, and the first portion 245a on the side surface of the liner film 240 may have the second thickness TH12. Furthermore, the second portion 245b on the lower surface of the liner film 240 may have a third thickness TH21, and the second portion 245b on the side surface of the liner film 240 may have a fourth thickness TH22. In this regard, the third thickness TH21 of the second portion 245b may be smaller than the first thickness TH11 of the first portion 245a. Alternatively, the fourth thickness TH22 of the second portion 245b may be smaller than the second thickness TH12 of the first portion 245a.

In FIG. 7A, it is shown that the first thickness TH11 and the second thickness TH12 are equal to each other, and the third thickness TH21 and the fourth thickness TH22 are equal to each other. However, this is only an example. In some cases, the first thickness TH11 and the second thickness TH12 may be different from each other, and the third thickness TH21 and the fourth thickness TH22 may be different from each other.

The shield conductive film 250 may be formed under the spacer film 245. The shield conductive film 250 may be formed in the first region I and may not be formed in the second region II. For example, the shield conductive film 250 may be disposed under a portion of the spacer film 245 of the first region I and may not be disposed under a portion of the spacer film 245 of the second region II so as to be exposed.

Portions of the shield conductive film 250 may be respectively interposed between adjacent ones of the conductive lines 210 of the first region I. For example, as shown in FIG. 1, the active patterns 110 may include a third active pattern 110C and a fourth active pattern 110D arranged along the second direction Y. The conductive lines 210 may include a first conductive line 210A in contact with the third active pattern 110C and a second conductive line 210B in contact with the fourth active pattern 110D. For example, in the first region I, the shield conductive film 250 may fill at least a portion of a region between the first conductive line 210A of and the second conductive line 210B. For example, the shield conductive film 250 may form a plurality of conductive shield lines 250-1 that linearly extend in the X direction, each of these conductive shield lines 250-1 being formed between adjacent ones of the conductive lines 210. In addition, as represented in FIG. 6, the conductive shield lines 250-1 may protrude vertically (in the Z direction) from a two dimensional conductive shield base 250-2 (e.g., in the form of a plate extending horizontally in the X and Y directions) of the shield conductive film 250 to be interconnected by the conductive shield base 250-2. Note that the cross sectional view of FIG. 1 illustrates the conductive shield lines 250-1 of the shield conductive film 250 but does not illustrate the interconnection of the conductive shield lines 250-1 by the conductive shield base 250-2. All of (or large portions of) the shield conductive film 250 may be continuous and the interconnected conductive shield lines 250-1 and conductive shield base 250-2 may form a single electrical node.

The shield conductive film 250 may include a conductive material, for example, at least one of doped polysilicon, a metal, a conductive metal nitride, a conductive metal silicide, a conductive metal oxide, or a combination thereof. The shield conductive film 250 may reduce coupling noise between adjacent conductive lines 210. For example, an internal voltage source of the memory device (not shown) may be electrically connected to the shield conductive film via wiring of the first wiring structures 280 and the second contacts 275 to apply a ground voltage to the shield conductive film 250.

In some embodiments, the shield conductive film 250 may include a metal film or a metal nitride film. In one example, the shield conductive film 250 may include a titanium nitride film (TiN film).

In some embodiments, a vertical level of the lowermost surface of the shield conductive film 250 may be lower than a vertical level of the lowermost surface of the spacer film 245. For example, the shield conductive film 250 may cover the lowermost surface of the portion of the spacer film 245 of the first region I.

The filling insulating film 260 may be formed under the shield conductive film 250 and the spacer film 245. The filling insulating film 260 may be disposed across the first region I and the second region II. For example, a portion of the filling insulating film 260 of the first region I may cover the shield conductive film 250, and a portion of the filling insulating film 260 of the second region II may cover the portion of the spacer film 245 of the second region II. Furthermore, the portion of the filling insulating film 260 of the second region II may include portions that extend between and are interposed between adjacent ones of the conductive lines 210 of the second region II. For example, in the second region II, the filling insulating film 260 may fill at least a portion of a region between the first conductive line 210A and the second conductive line 210B.

The filling insulating film 260 may include, but is not limited to, at least one of silicon oxide, silicon nitride, silicon oxynitride, silicon oxycarbonitride, or a combination thereof.

First contacts 270 may be disposed in the second region II. Each of the conductive lines 210 may be in contact with a corresponding first contact 270. For example, the first contact 270 may extend through the filling insulating film 260, the spacer film 245, the liner film 240, and the capping film 220 so as to be in contact with the lower surface of each of the conductive lines 210.

One or more second contacts 275 may be disposed in the first region I. The second contact(s) 275 may be in contact with the shield conductive film 250. For example, the second contact(s) 275 may extend through the filling insulating film 260 so as to contact the lower surface of the shield conductive film 250.

The first wiring structure 280 may be formed under the filling insulating film 260. For example, a first inter-wiring insulating film 290 may be formed on a lower surface of the filling insulating film 260. The first wiring structure 280 may be formed within the first inter-wiring insulating film 290 as a patterned conductor with discrete (separated) patterned elements thereof forming wires to that provide corresponding electrical paths connected to the gate electrodes 150, the back gate electrodes 130, the conductive lines 210, and/or the shield conductive film 250. For example, some pattern elements of the first wiring structure 280 may be electrically connected to the conductive lines 210 via the first contact 270. For example, other pattern elements the first wiring structure 280 may be electrically connected to the shield conductive film 250 via the second contact 275. The number of layers and arrangement of the first wiring structure 280 are only examples, and are not limited to those illustrated.

Referring to FIGS. 1 to 6 and FIG. 7B, in a semiconductor memory device according to some embodiments, the third thickness TH21 of the second portion 245b is smaller than the fourth thickness TH22 of the second portion 245b.

In some embodiments, the third thickness TH21 of the second portion 245b may be smaller than the first thickness TH11 of the first portion 245a, and the fourth thickness TH22 of the second portion 245b may be smaller than the second thickness TH12 of the first portion 245a.

Referring to FIGS. 1 to 6 and FIG. 7C, in a semiconductor memory device according to some embodiments, the second portion 245b of the spacer film 245 does not extend along the lower surface of the conductive lines 210. For example, the second portion 245b of the spacer film 245 may extend along the side surface of the liner film 240 and may not cover the lower surface of the liner film 240 so as to be exposed.

Referring to FIGS. 1 to 6 and FIG. 7D, in a semiconductor memory device according to some embodiments, the third thickness TH21 of the second portion 245b is smaller than the first thickness TH11 of the first portion 245a, and the fourth thickness TH22 of the second portion 245b is equal to the second thickness TH12 of the first portion 245a. As used herein, “being equal” means not only exactly equal but also including a slight difference that may occur due to a process margin, etc.

Referring to FIGS. 1 to 6 and FIG. 7E, in a semiconductor memory device according to some embodiments, the spacer film 245 in the second region (the second portion 245b of the spacer film 245) does not extend along the lower surface of the conductive lines 210. For example, the second portion 245b of the spacer film 245 may extend along the side surface of the liner film 240 and may not cover the lower surface of the liner film 240 so as to expose the liner film 240 with respect to the spacer film 245.

In some embodiments, the fourth thickness TH22 of the second portion 245b may be equal to the second thickness TH12 of the first portion 245a and such structure may be implemented by all of the embodiments described herein (with the exception of this difference).

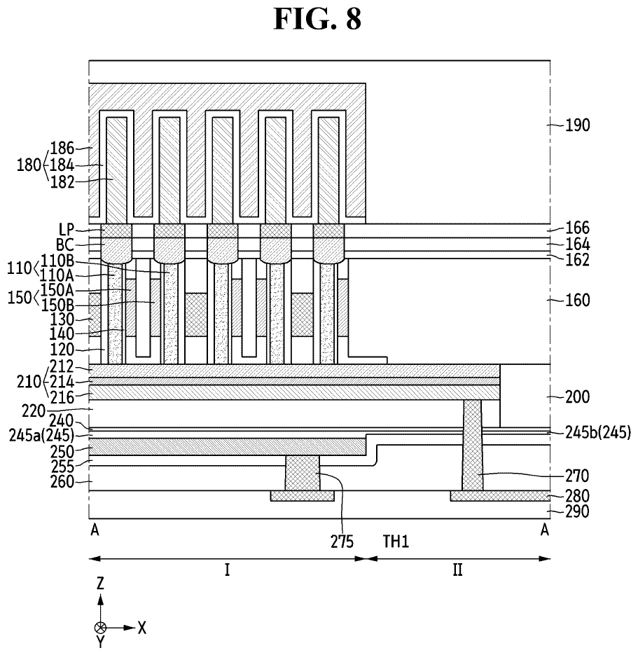

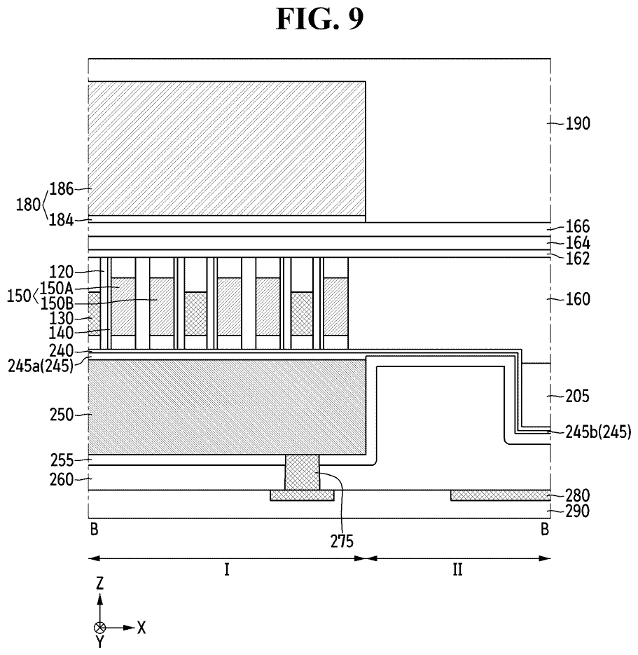

FIGS. 8 and 9 are cross-sectional views for illustrating a semiconductor memory device according to some embodiments. FIG. 8 is a cross-sectional view taken along a line A-A of FIG. 1. FIG. 9 is a cross-sectional view taken along a line B-B of FIG. 1. For convenience of description, contents that duplicate with those as described above using FIGS. 1 to 7E are briefly described or descriptions thereof are omitted, but it should be understood that such features of these embodiments are applicable to the embodiment of FIGS. 8 and 9.

Referring to FIGS. 8 and 9, a semiconductor memory device according to some embodiments further includes a capping insulating film 255.

The capping insulating film 255 may be formed under the shield conductive film 250 and the spacer film 245. In the first region I, a portion of the capping insulating film 255 may be interposed between the shield conductive film 250 and the filling insulating film 260, and in the second region II, a portion of the capping insulating film 255 may be interposed between the spacer film 245 and the filling insulating film 260. For example, the capping insulating film 255 may conformally extend along and on the lower surface and the side surface of the shield conductive film 250, and the lower surface and the side surface of the second portion 245b of the spacer film 245.

The capping insulating film 255 may include, but is not limited to, at least one of silicon oxide, silicon nitride, silicon oxynitride, silicon oxycarbonitride, or a combination thereof. In one example, the capping insulating film 255 may include a silicon nitride film.

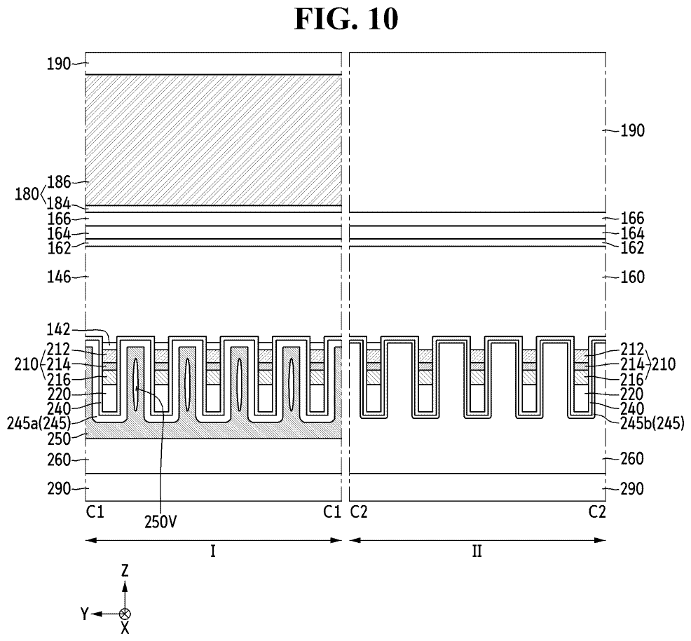

FIG. 10 is a cross-sectional view taken along lines C1-C1 and C2-C2 of FIG. 1 illustrating a semiconductor memory device according to some embodiments. For convenience of description, contents duplicate with those as described above using FIGS. 1 to 9 are briefly described or descriptions thereof are omitted, but it should be understood that such features of these embodiments are applicable to the embodiment of FIG. 10.

Referring to FIG. 10, in the semiconductor memory device according to some embodiments, the shield conductive film 250 contains therein a void 250V.

The void 250V may be formed within the shield conductive film 250 and between the conductive lines 210. The void 250V may be an empty space and/or an air gap (containing a gas, such as air or gas of the manufacturing environment). Since this void 250V may have a low dielectric constant, the void may reduce the parasitic capacitance between the conductive lines 210.

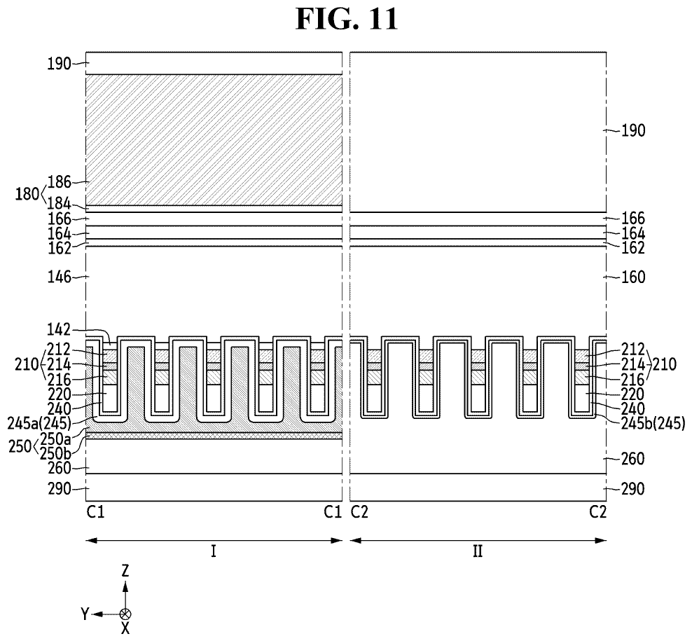

FIG. 11 is a cross-sectional view taken along lines C1-C1 and C2-C2 of FIG. 1 illustrating a semiconductor memory device according to some embodiments. For convenience of description, contents duplicate with those as described above using FIGS. 1 to 10 are briefly described or descriptions thereof are omitted, but it should be understood that such features of these embodiments are applicable to the embodiment of FIG. 11.

Referring to FIG. 11, in the semiconductor memory device according to some embodiments, the shield conductive film 250 includes a filling conductive film 250a and a plate conductive film 250b. The filling conductive film 250a may include the plurality of conductive shield lines 250-1 interconnected by the conductive shield base 250-2 as described elsewhere (e.g., refer to FIG. 6).

The filling conductive film 250a and the plate conductive film 250b may be sequentially formed under the first portion 245a of the spacer film 245.

The filling conductive film 250a may fill at least a portion of a region defined between the conductive lines 210 of the first region I. In some embodiments, a vertical level of the lowermost surface of the filling conductive film 250a may be lower than a vertical level of the lowermost surface of the spacer film 245. For example, the filling conductive film 250a may cover the lowermost surface of the portion of the spacer film 245 of the first region I. The filling conductive film 250a may include a metal film or a metal nitride film. In one example, the filling conductive film 250a may include a titanium nitride film (TiN film).

The plate conductive film 250b may extend along and on a lower surface of the filling conductive film 250a (e.g., along the surface of conductive shield base 250-2). The plate conductive film 250b may include a metal film having a lower electrical resistance than that of the filling conductive film 250a. In one example, the plate conductive film 250b may include a tungsten film (W film).

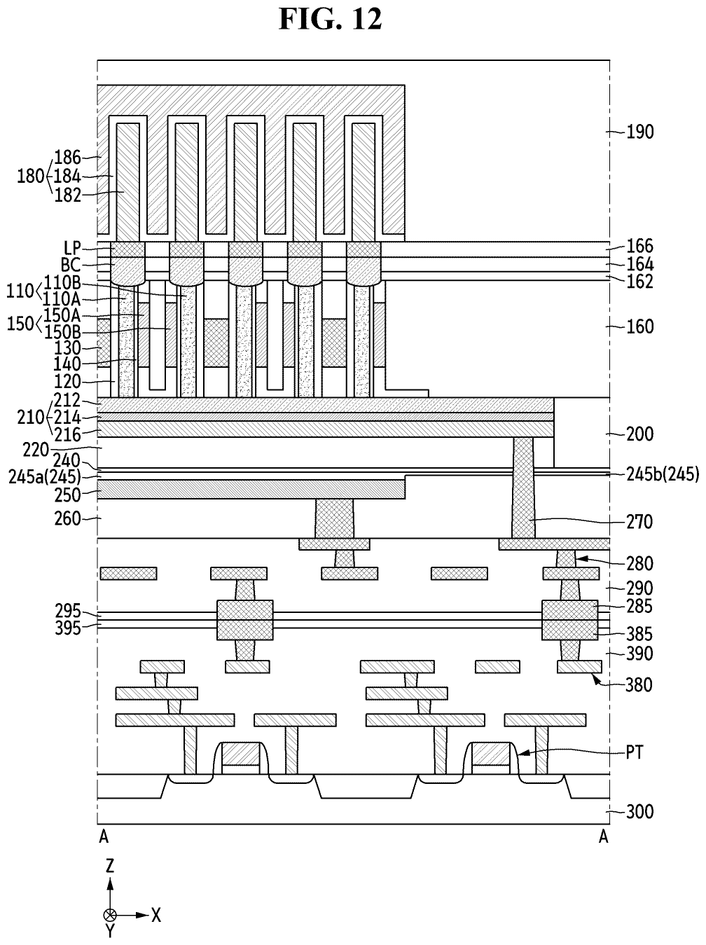

FIG. 12 is a cross-sectional view taken along A-A of FIG. 1 for illustrating a semiconductor memory device according to some embodiments. For convenience of description, contents duplicate with those as described above using FIGS. 1 to 11 are briefly described or descriptions thereof are omitted, but it should be understood that such features of these embodiments are applicable to the embodiment of FIG. 12.

Referring to FIG. 12, the semiconductor memory device according to some embodiments further includes a substrate 300, a peripheral circuit PT, and a second wiring structure 380.

The substrate 300 may be a base semiconductor substrate (an initial substate in and/or on which circuitry is formed), such as a semiconductor bulk substrate, such as a silicon bulk substrate, a germanium bulk substrate, or a silicon-germanium bulk substrate, for example. Alternatively, the substrate 300 may be a silicon-on-insulator (SOI) substrate or a germanium-on-insulator (GOI) substrate, etc.

The peripheral circuit PT may be formed in and/or on the substrate 300. The peripheral circuit PT may constitute a peripheral circuit that controls an operation of the semiconductor memory device (such as the operation of the memory cells of the memory cell array). The peripheral circuit PT may includer transistors interconnected to form logic gates. The peripheral circuit may include a row decoder, a column decoder, an address decoder, I/O circuits, and/or an external interface (e.g., I/O buffer) for communication with external devices). However, embodiments of the present disclosure are not limited thereto. For example, the peripheral circuit PT may include various active elements such as a transistor, as well as various passive elements such as a capacitor, a resistor, and an inductor.

The second wiring structure 380 may be formed on the peripheral circuit PT. For example, a second inter-wiring insulating film 390 may be formed on the substrate 300 and may constitute a patterned conductor forming wires as described with respect to the first wiring structure 280. The second wiring structure 380 may be formed within the second inter-wiring insulating film 390 forming wires that provide electrical paths that form interconnects of the peripheral circuit(s) PT (e.g., forming or interconnecting logic gates of the peripheral circuit(s) PT). The number of layers and arrangement of the second wiring structure 380 are merely examples and are not limited to those illustrated.

The semiconductor memory device according to some embodiments may have a C2C (chip to chip) structure. The C2C structure may be obtained by manufacturing an upper chip including a memory cell structure on a first wafer, manufacturing a lower chip including a peripheral circuit structure on a second wafer different from the first wafer, and then connecting the upper chip and the lower chip to each other in a bonding scheme (e.g., direct connection via hybrid bonding).

In one example, the bonding scheme may mean a scheme of connecting (e.g., contacting and bonding) a first bonding metal 285 (and/or a first bonding insulating film 295) formed as an uppermost metal layer of the upper chip and a second bonding metal 385 (and/or a second bonding insulating film 395) formed as an uppermost metal layer of the lower chip to each other. For example, when each of the first bonding metal 285 and the second bonding metal 385 is made of copper (Cu), the bonding scheme may be a Cu-Cu bonding scheme. However, this is only an example, and each of the first bonding metal 285 and the second bonding metal 385 may be made of each of various other metals such as aluminum (Al) or tungsten (W).

As the first bonding metal 285 and the second bonding metal 385 are bonded to each other, the first wiring structure 180 may be electrically connected to the second wiring structure 280. Thus, a plurality of memory cells may be electrically connected to the peripheral circuit PT.

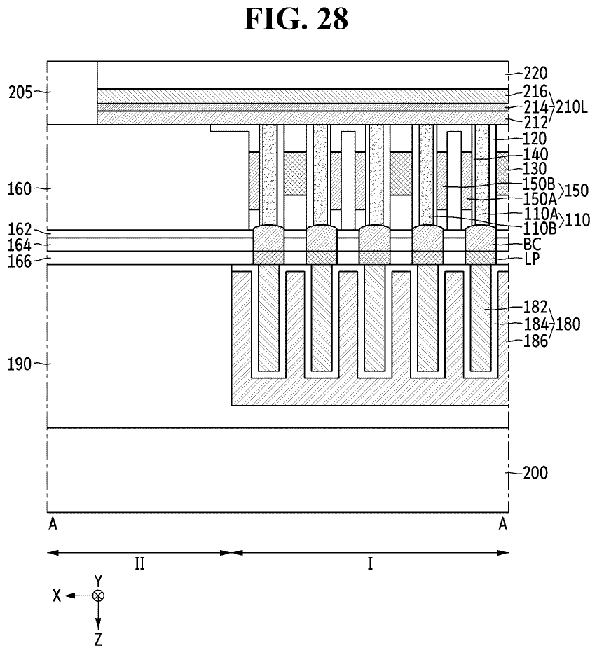

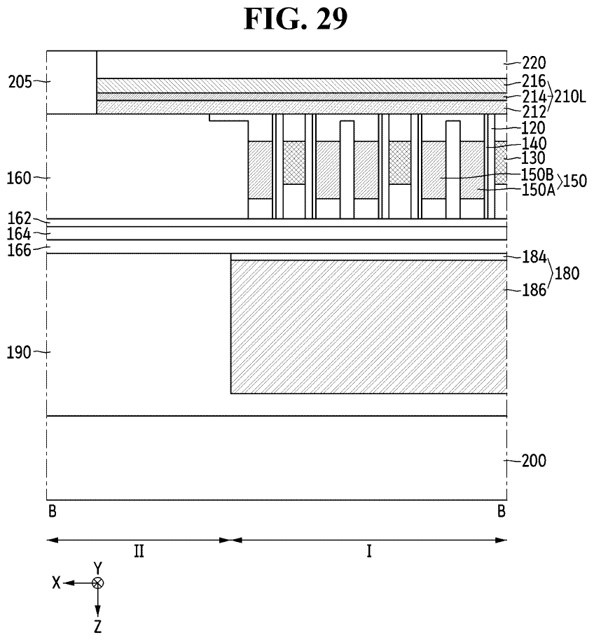

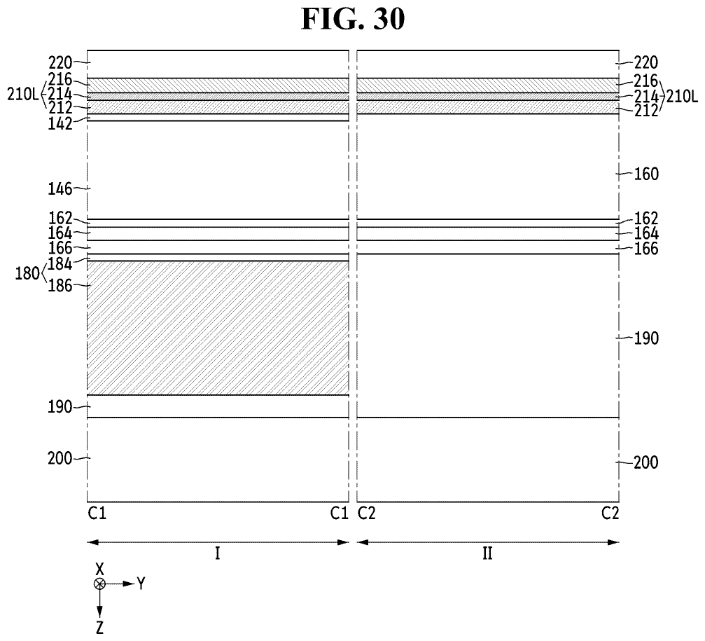

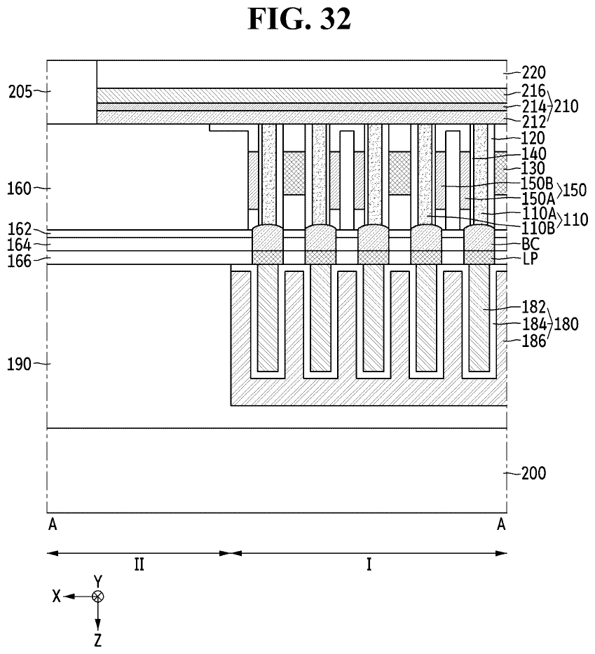

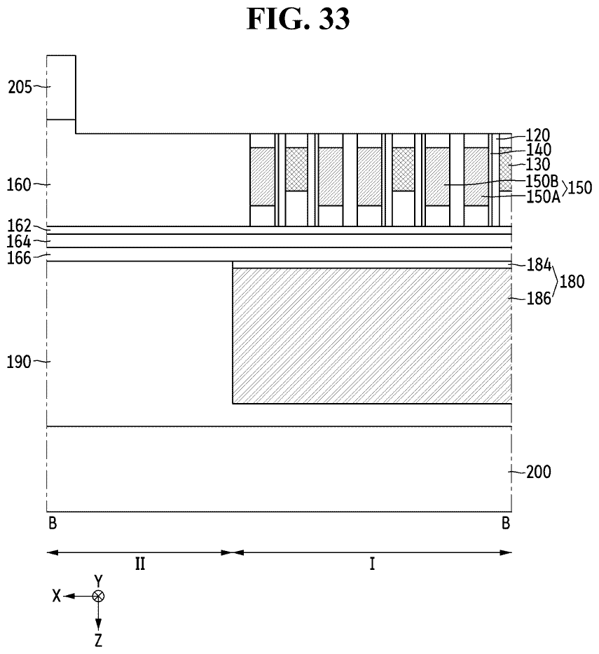

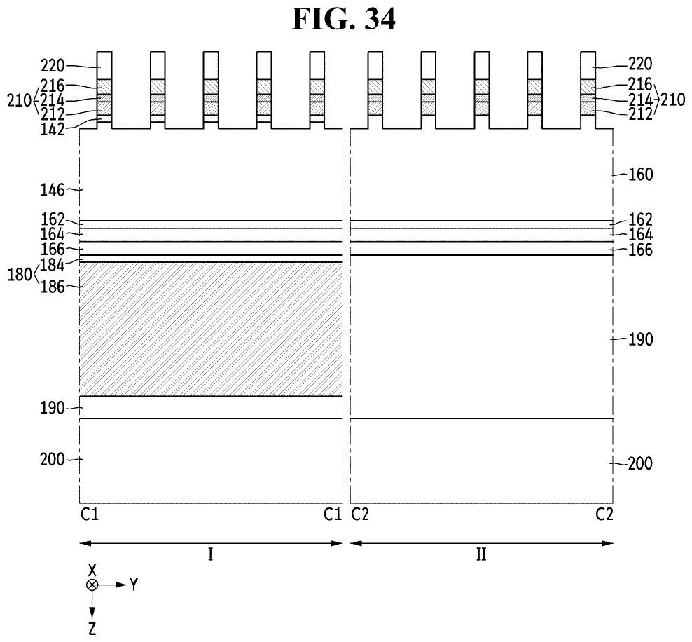

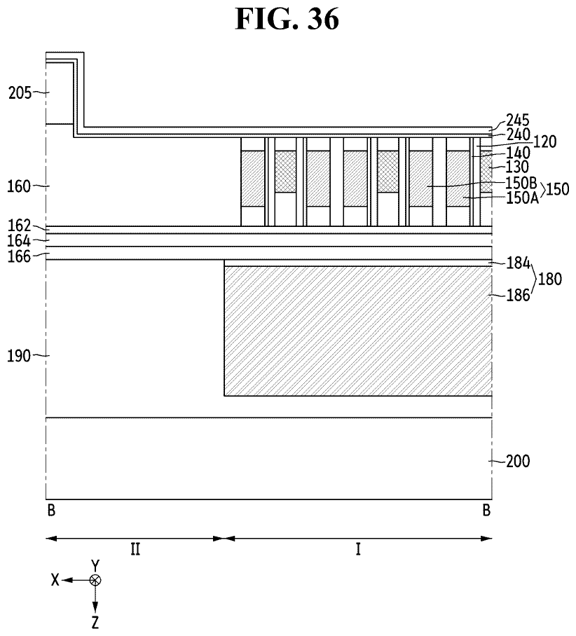

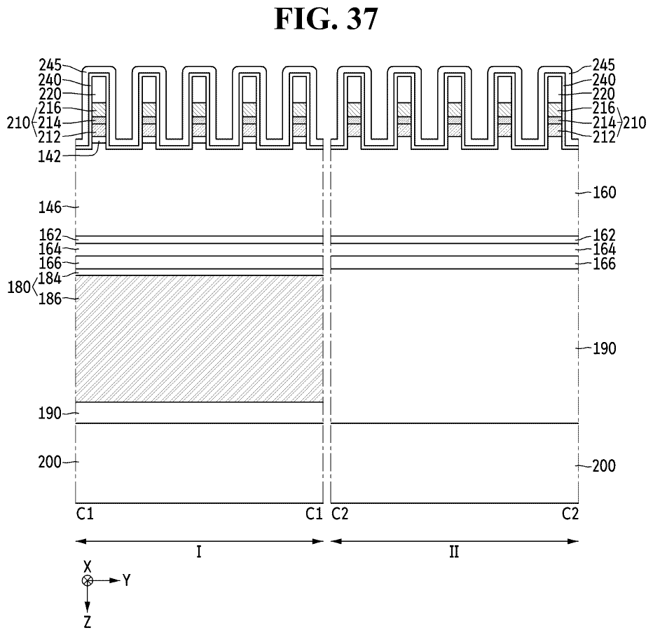

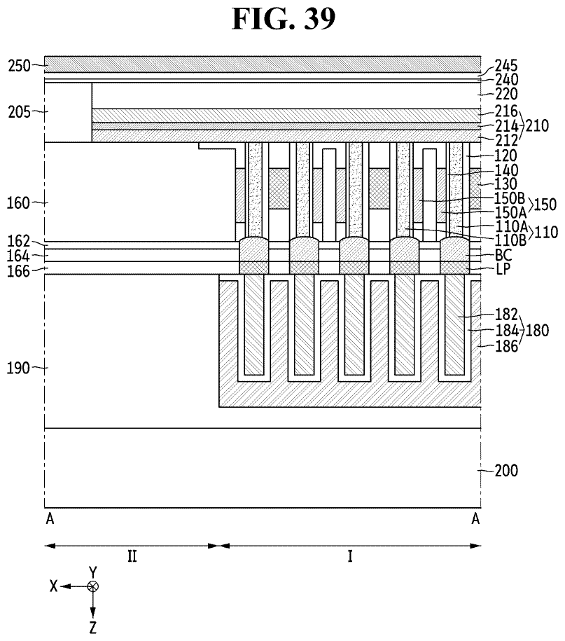

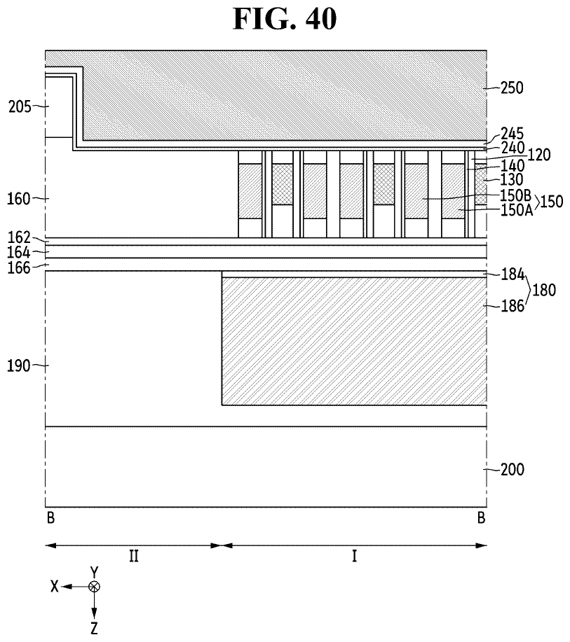

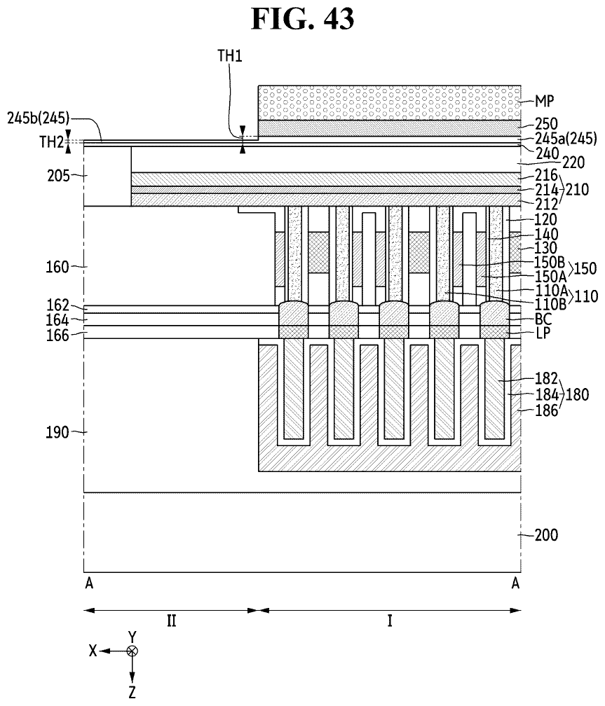

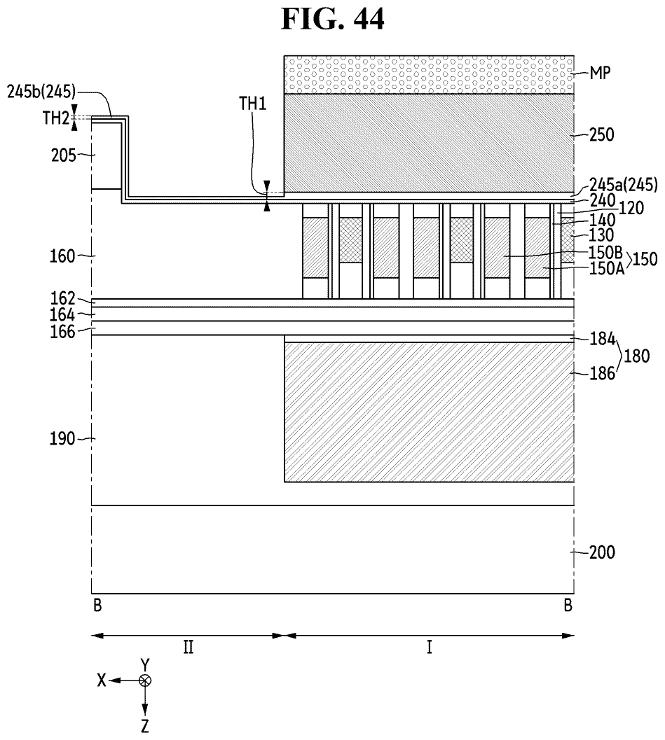

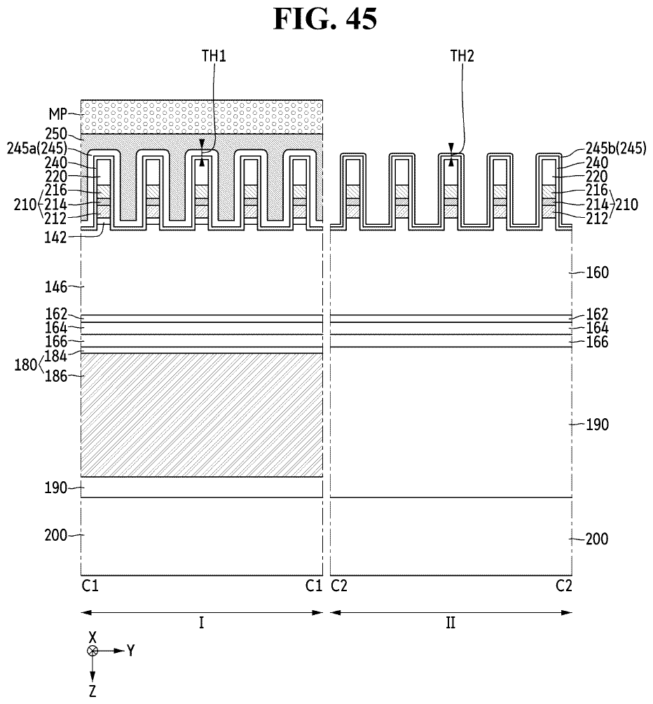

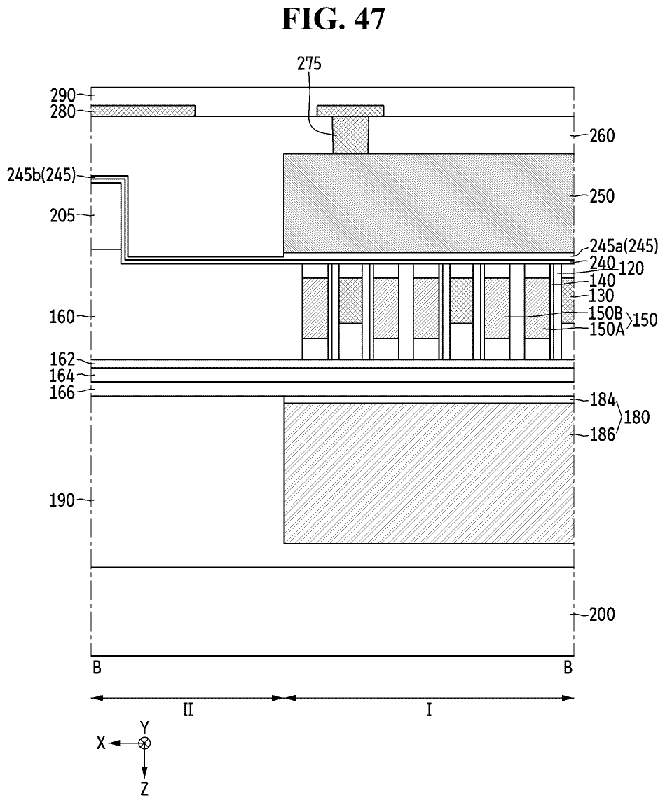

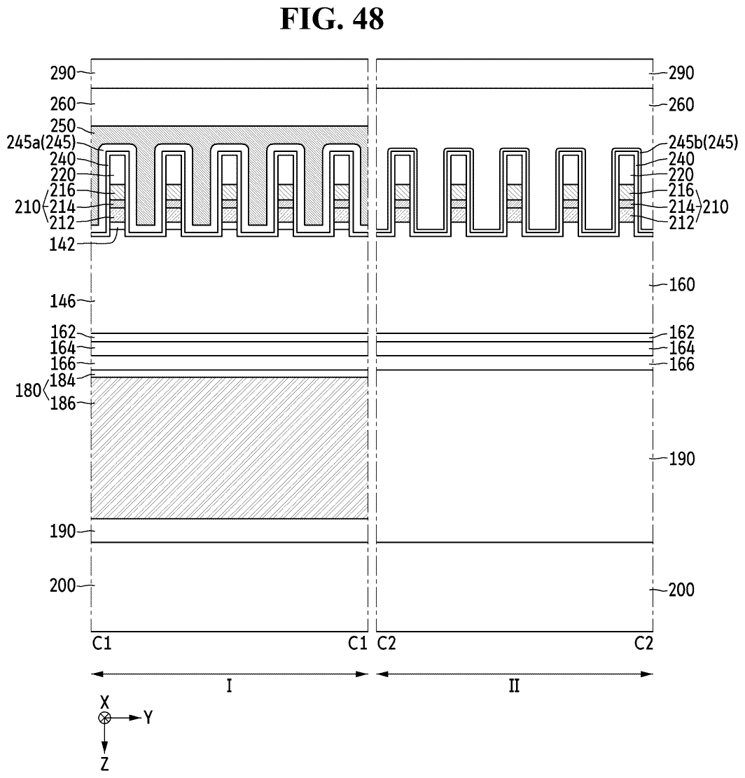

Hereinafter, with reference to FIGS. 1 to 48, a semiconductor memory device according to some embodiments will be described.

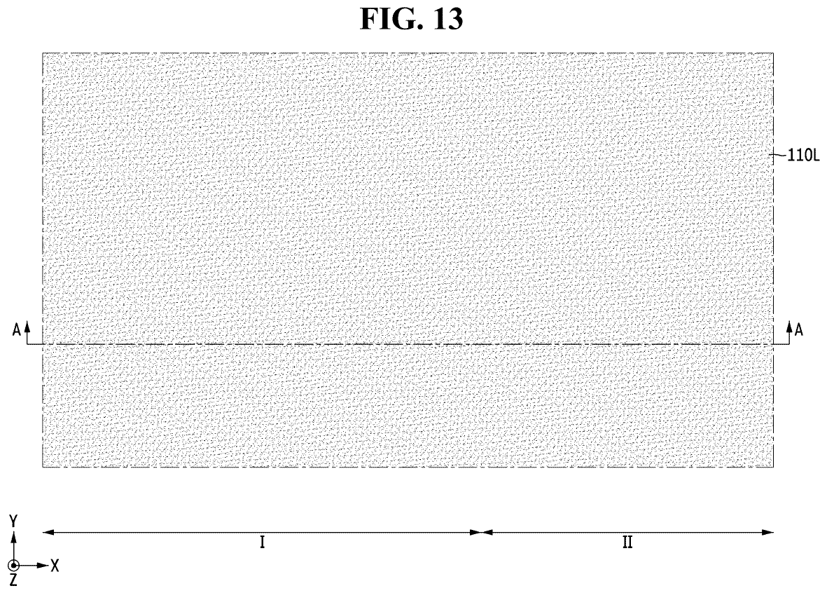

FIGS. 13 to 48 are diagrams of intermediate structures corresponding to intermediate steps of a method for manufacturing a semiconductor memory device according to some embodiments. For convenience of description, contents duplicate with those as described above using FIGS. 1 to 12 are briefly described or descriptions thereof are omitted but will be understood to be applicable to embodiments of FIGS. 13 to 48.

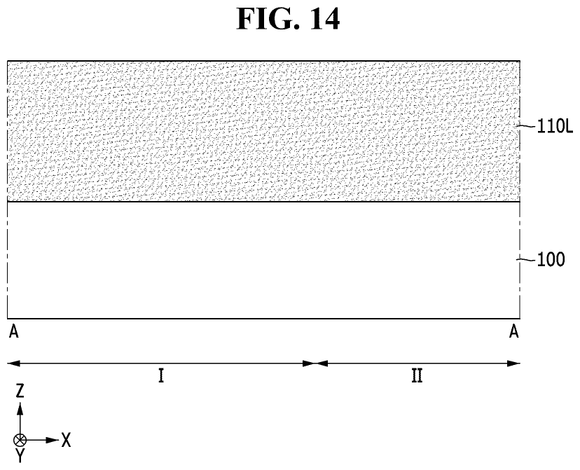

Referring to FIG. 13 and FIG. 14, an active film 110L is formed on a base substrate 100.

The active film 110L may include a semiconductor material. For example, the active film 110L may include silicon, silicon germanium, (SGOI) silicon germanium on insulator, indium antimonide, lead telluride compound, indium arsenide, indium phosphide, gallium arsenide, or gallium antimonide. The active film 110L may be a single crystalline layer or formed of multiple layers made of the semiconductor material. In some embodiments, the active film 110L may be a crystalline semiconductor material. In one example, the active film 110L may be formed of crystalline silicon.

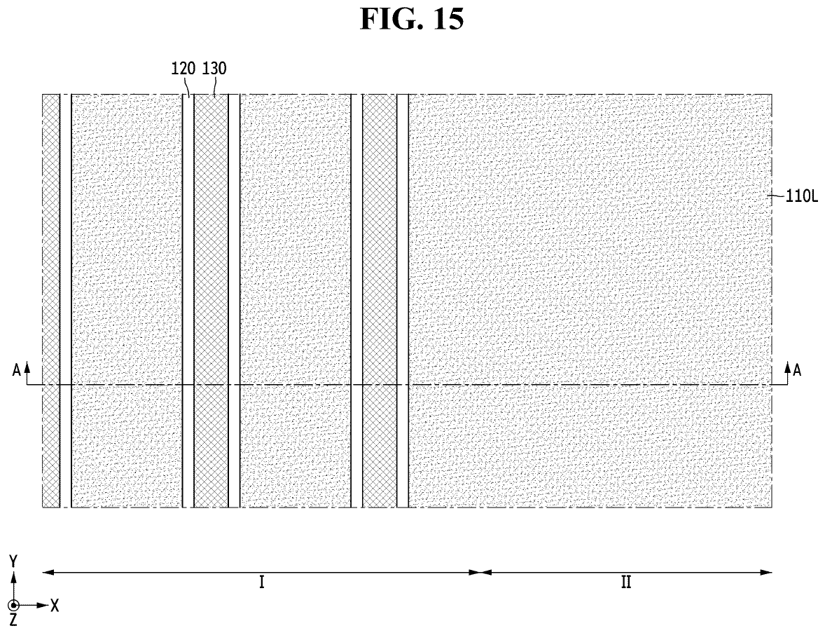

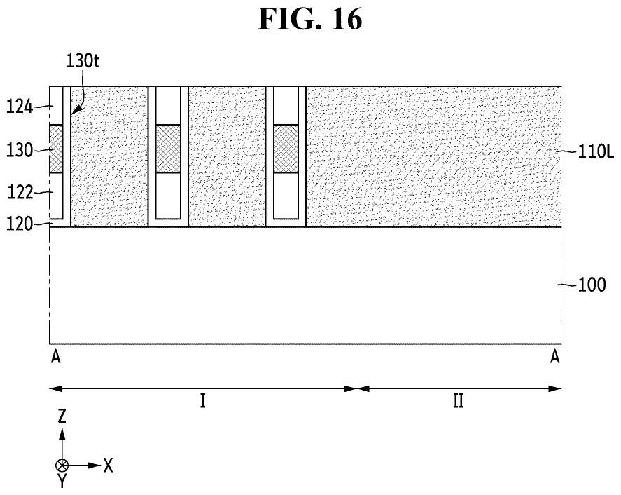

Referring to FIG. 15 and FIG. 16, the back gate dielectric film 120 and the back gate electrodes 130 are formed within the active film 110L.

For example, a first gate trench 130t extending in the second direction Y may be formed within the active film 110L. The back gate dielectric film 120 may be formed within the first gate trench 130t. The back gate dielectric film 120 may conformally extend along and on a lower surface and a side surface of the first gate trench 130t. Subsequently, the second lower spacer pattern 122, the back gate electrode 130, and the second upper spacer pattern 124 may be sequentially formed on the back gate dielectric film 120. The second lower spacer pattern 122, the back gate electrode 130, and the second upper spacer pattern 124 may fill a region of the first gate trench 130t remaining after the back gate dielectric film 120 has been formed therein.

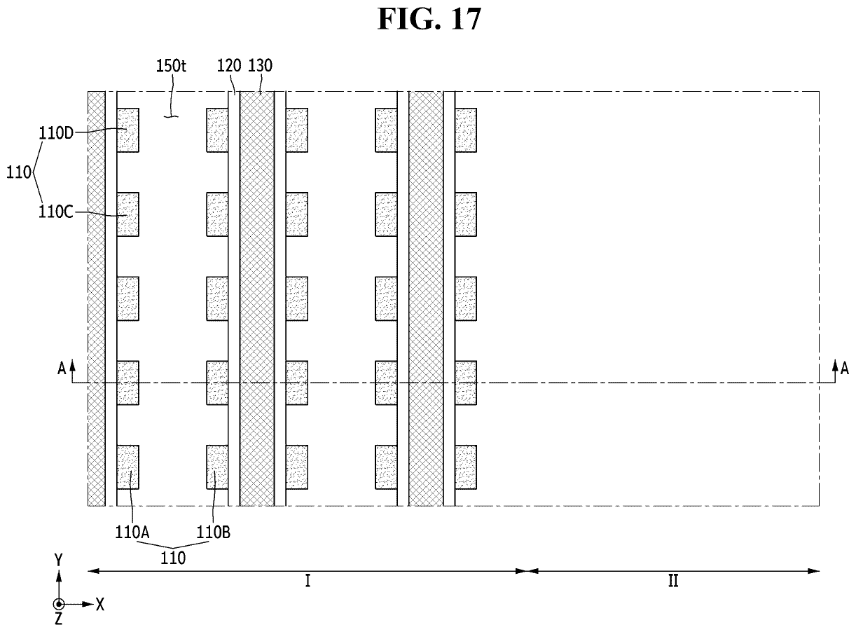

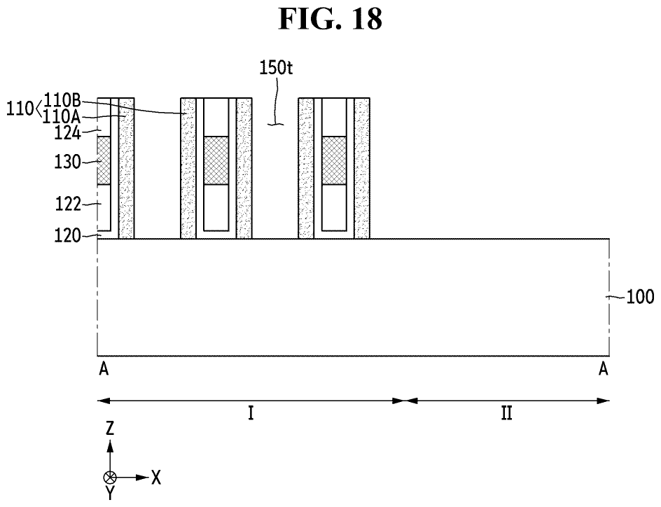

Referring to FIG. 17 and FIG. 18, the active patterns 110 are formed.

The active patterns 110 may be formed in the first region I. The active patterns 110 may be arranged two-dimensionally along the horizontal plane. For example, a patterning process on the active film 110L of FIG. 15 and FIG. 16 may be performed, so that a plurality of active patterns 110 arranged in a matrix form along the first direction X and the second direction Y may be formed.

In some embodiments, a second gate trench 150t extending in the second direction Y may be formed on the base substrate 100. The first active pattern 110A and the second active pattern 110B may be formed within the second gate trench 150t .

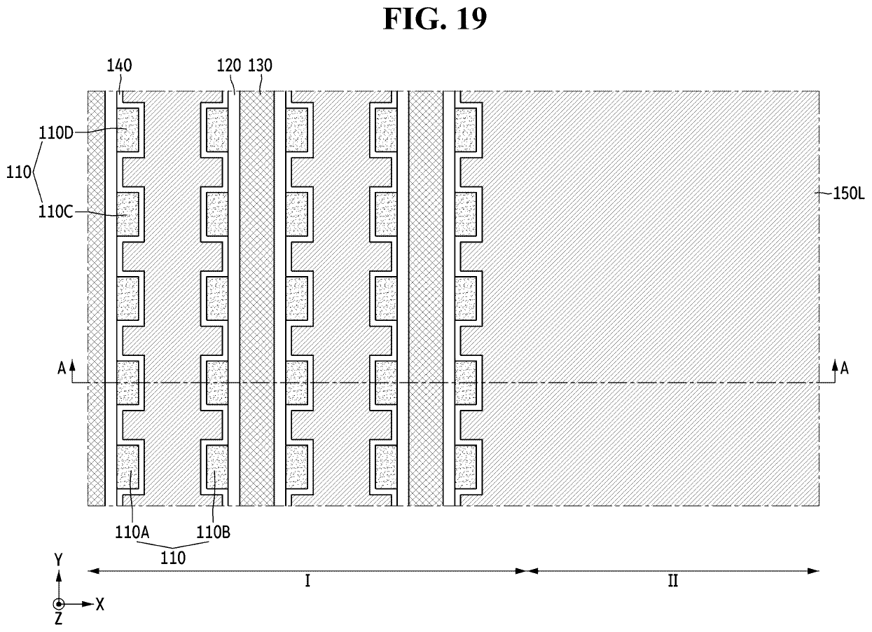

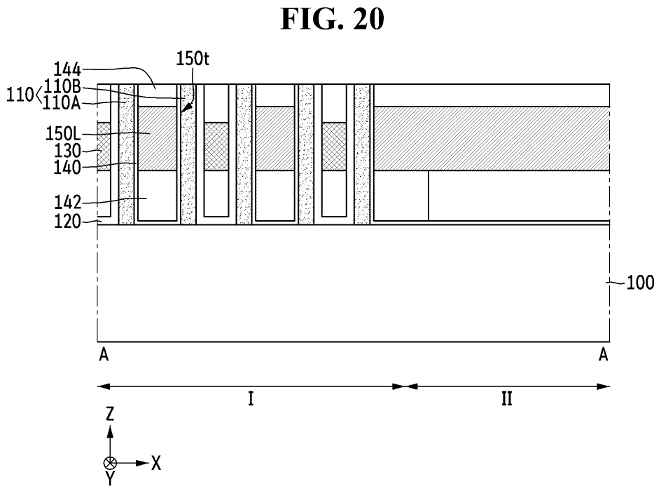

Referring to FIG. 19 and FIG. 20, the gate dielectric film 140 and the gate electrode film 150L are formed on the side surfaces of the active patterns 110.

The gate dielectric film 140 may be formed within the second gate trench 150t. The gate dielectric film 140 may conformally extend along and on a lower surface and a side surface of the second gate trench 150t. Next, the first lower spacer pattern 142, the gate electrode film 150L, and the first upper spacer pattern 144 may be sequentially formed on the gate dielectric film 140. The first lower spacer pattern 142, the gate electrode film 150L, and the first upper spacer pattern 144 may fill a region of the second gate trench 150t that remains after the gate dielectric film 140 has been formed therein.

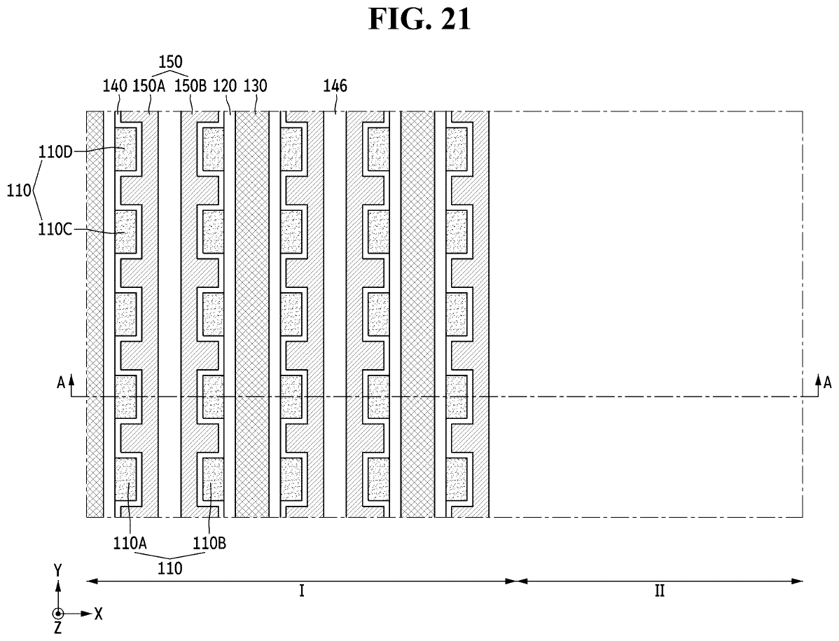

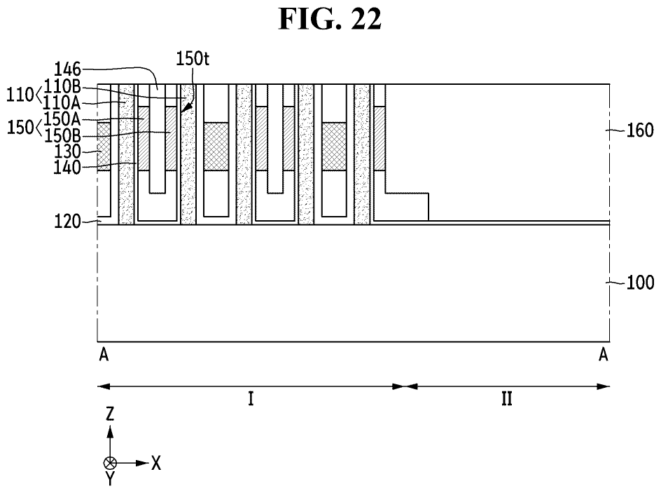

Referring to FIG. 21 and FIG. 22, the isolation insulating film 146 and the first interlayer insulating film 160 are formed.

The isolation insulating film 146 may be formed within the second gate trench 150t. The isolation insulating film 146 may extend lengthwise 3 in the second direction Y to cut the gate electrode film 150L of FIG. 19 and FIG. 20. Thus, the gate electrodes 150 including the first gate electrode 150A and the second gate electrode 150B may be formed.

The first interlayer insulating film 160 may fill the space on the outer side surface of each of the active patterns 110, the gate electrodes 150, and the back gate electrodes 130.

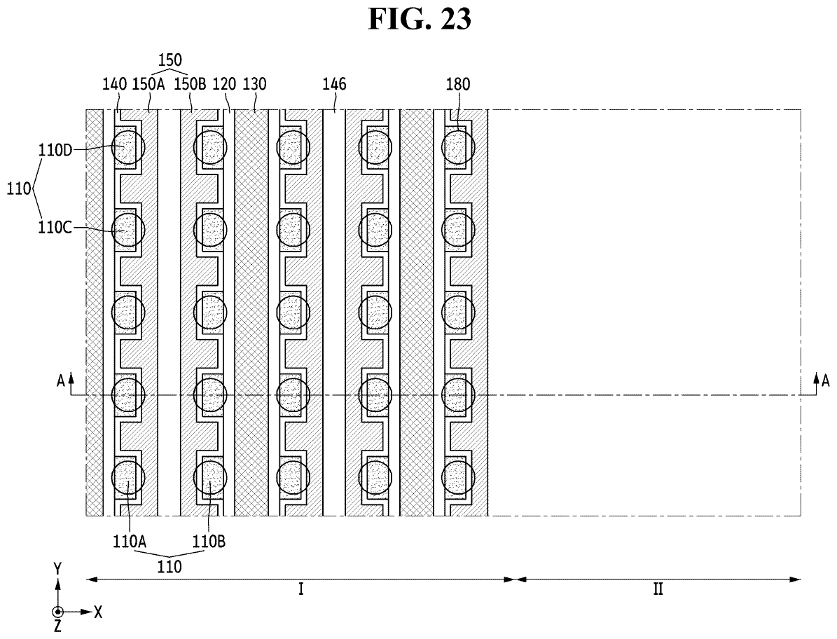

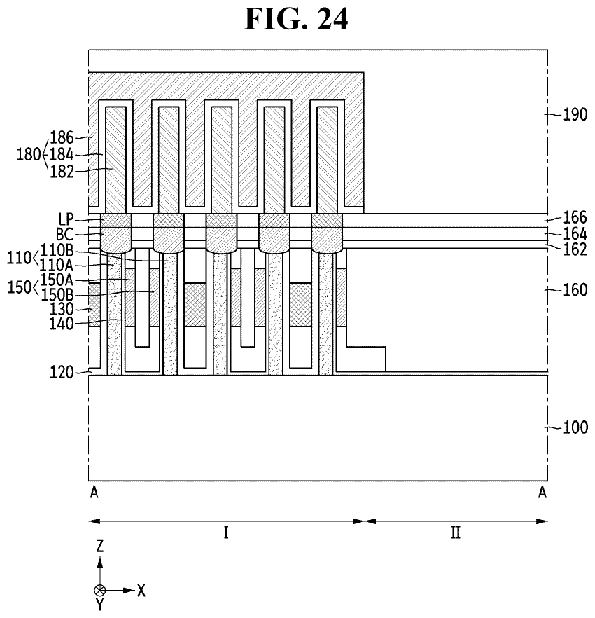

Referring to FIG. 23 and FIG. 24, the contact patterns BC, the landing pads LP, and the data storage structures 180 are formed.

For example, the etch-stop film 162 and the second interlayer insulating film 164 may be sequentially stacked on the upper surfaces of the active patterns 110, the gate electrodes 150, the back gate electrodes 130, and the first interlayer insulating film 160. The contact patterns BC may extend through the etch-stop film 162 and the second interlayer insulating film 164 so as to contact each of the active patterns 110.

Subsequently, the third interlayer insulating film 166 may be stacked on an upper surface of the second interlayer insulating film 164. The landing pads LP may extend through the third interlayer insulating film 166 so as to contact the contact patterns BC.

Next, the data storage structures 180 may be formed on the landing pads LP and the third interlayer insulating film 166. The data storage structure 180 may include the lower electrode 182, the capacitor dielectric film 184, and the upper electrode 186 that are sequentially stacked on a corresponding landing pad LP. After the data storage structures 180 have been formed, the upper insulating film 190 covering the third interlayer insulating film 166 and the data storage structures 180 may be formed.

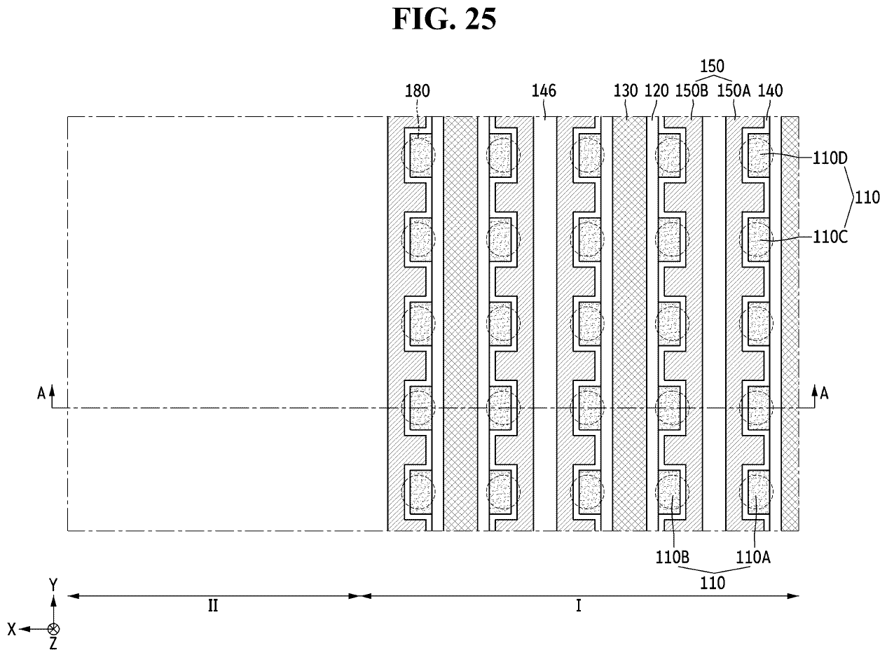

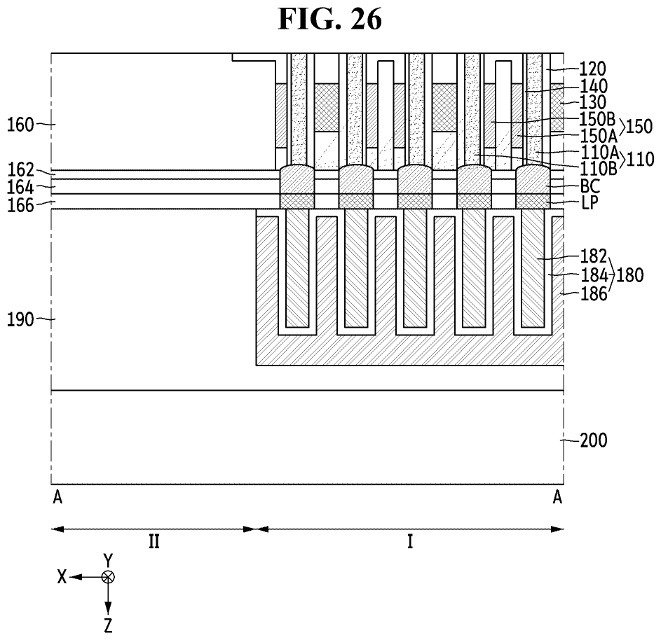

Referring to FIG. 25 and FIG. 26, the base substrate 100 is removed.

For example, a carrier substrate 200 may be attached to a resulting structure of FIG. 23 and FIG. 24. After the carrier substrate 200 has been attached thereto, the resulting structure of FIG. 23 and FIG. 24 may be turned upside down.

Next, a thinning process on the base substrate 100 may be performed. The thinning process may include, but is not limited to, a back grinding process on a back surface of the base substrate 100. As the thinning process is performed, the active patterns 110 may be exposed.

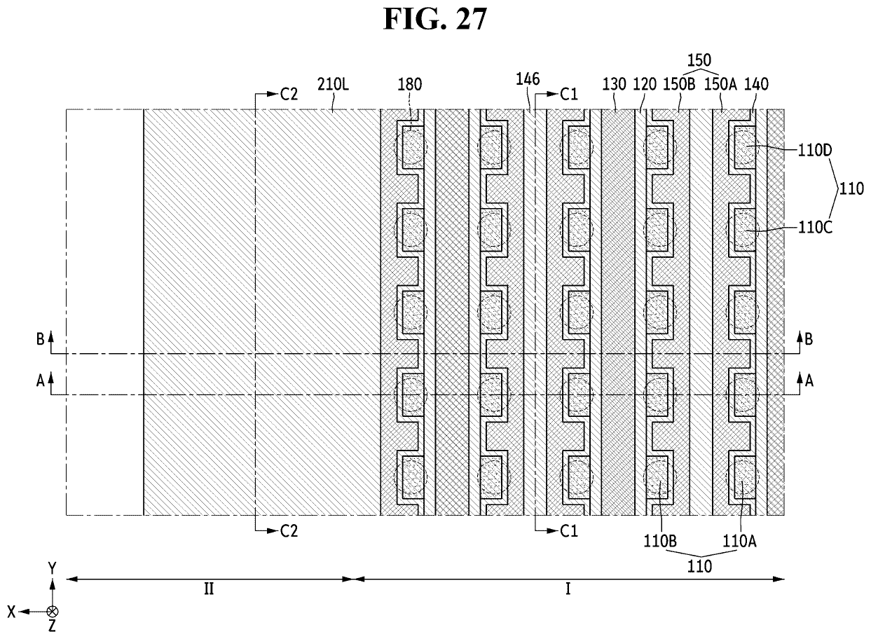

Referring to FIGS. 27 to 30, the conductive pattern 210L and the capping film 220 are formed.

The conductive pattern 210L may be in contact with the active patterns 110. For example, the conductive pattern 210L may include the first conductive film 131, the second conductive film 132, and the third conductive film 133 that are sequentially stacked on the active patterns 110. The conductive pattern 210L may be disposed across the first region I and the second region II. The capping film 220 may extend along and on the upper surface of the conductive pattern 210L.

In some embodiments, the conductive pattern 210L may have an end disposed in the second region II. For example, the fourth interlayer insulating film 205 may be formed in the second region II. The fourth interlayer insulating film 205 may define an end of the conductive pattern 210L in the first direction X.

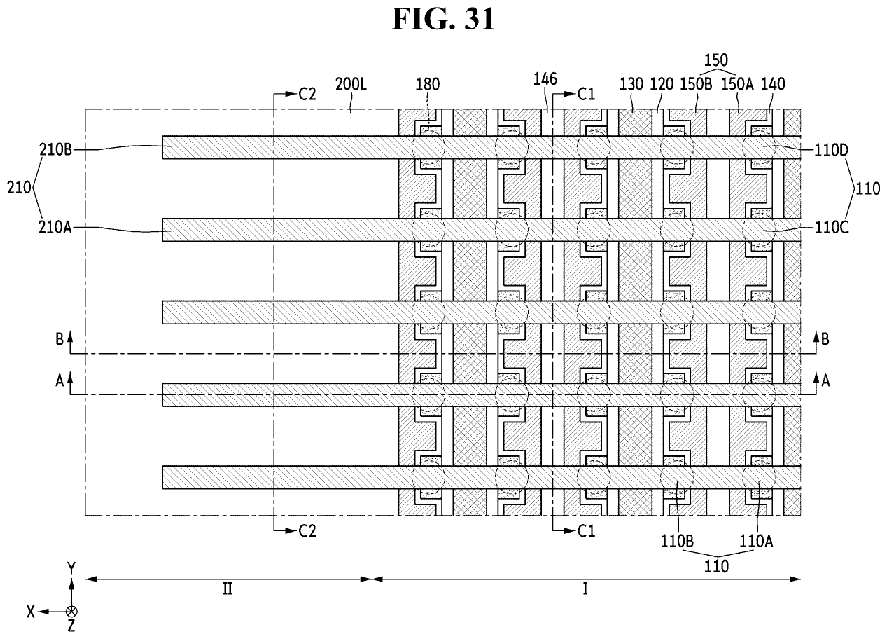

Referring to FIGS. 31 to 34, the conductive lines 210 are formed.

For example, a patterning process may be performed on the conductive pattern 210L and the capping film 220 of FIGS. 27 to 30. As the patterning process is performed, the conductive lines 210 may be formed so as to extend in the first direction X and across the first region I and the second region II.

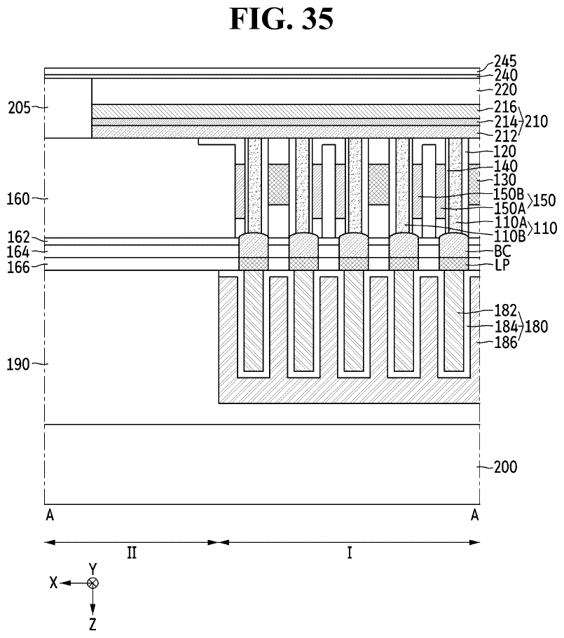

Referring to FIG. 35 to FIG. 37, the liner film 240 and the spacer film 245 are sequentially formed on the conductive lines 210.

The liner film 240 may be stacked on the first interlayer insulating film 160, the conductive lines 210, and the capping film 220. For example, the liner film 240 may conformally extend along and on the side surface of the conductive lines 210, and the side surface and the lower surface of the capping film 220.

The spacer film 245 may be stacked on the liner film 240. For example, the spacer film 245 may conformally extend along and on the side surface and the lower surface of the liner film 240.

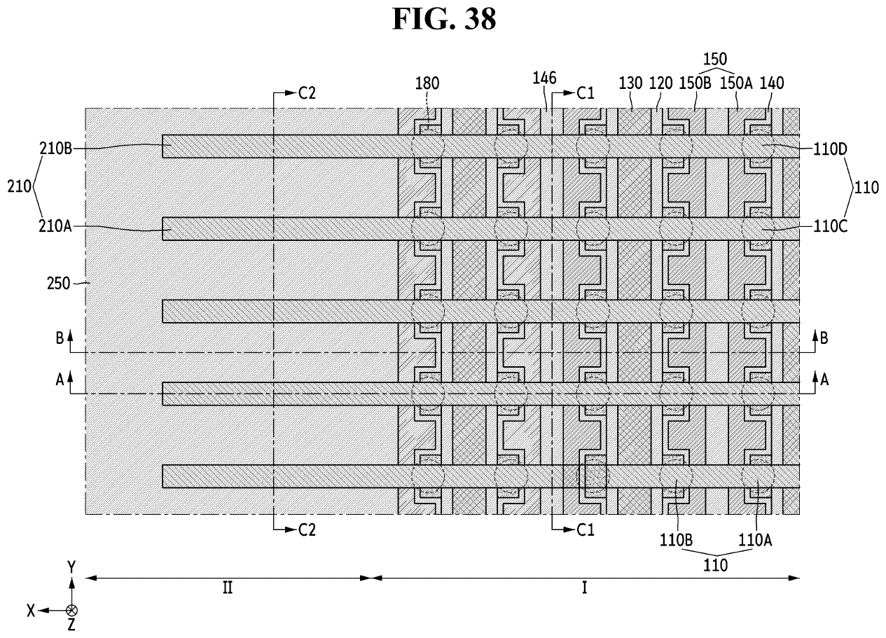

Referring to FIG. 38 to FIG. 41, the shield conductive film 250 is formed on the spacer film 245.

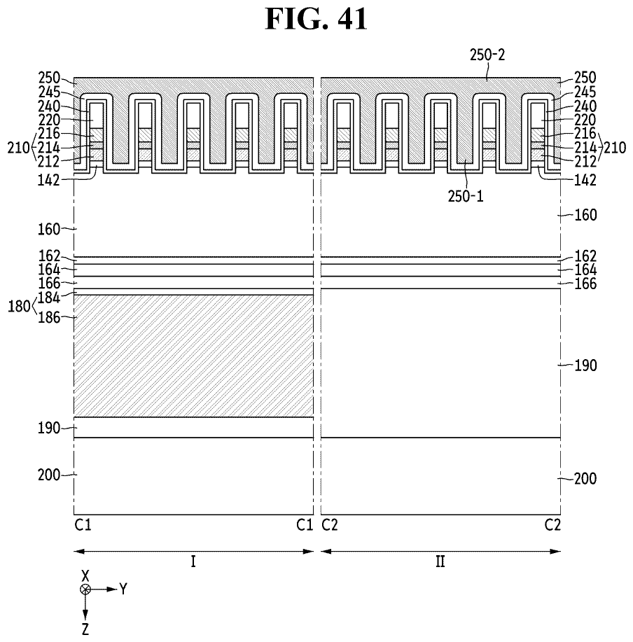

The shield conductive film 250 may cover the spacer film 245 and may be disposed across the first region I and the second region II. At least a portion of the shield conductive film 250 may be interposed between the conductive lines 210. For example, the shield conductive film 250 may fill at least a portion of the region defined between the first conductive line 210A and second conductive line 210B. As shown in FIG. 41, the shield conductive film 250 may form a plurality of conductive shield lines 250-1 that linearly extend in the X direction, each of these conductive shield lines 250-1 being formed between adjacent ones of the conductive lines 210. In addition, the conductive shield lines 250-1 may extend (in the Z direction) from a two dimensional conductive shield base 250-2 (e.g., in the form of a plate extending horizontally in the X and Y directions) of the shield conductive film 250 to be interconnected by the conductive shield base 250-2

In some embodiments, the shield conductive film 250 may include a metal film or a metal nitride film. In one example, the shield conductive film 250 may include a titanium nitride film (TiN film).

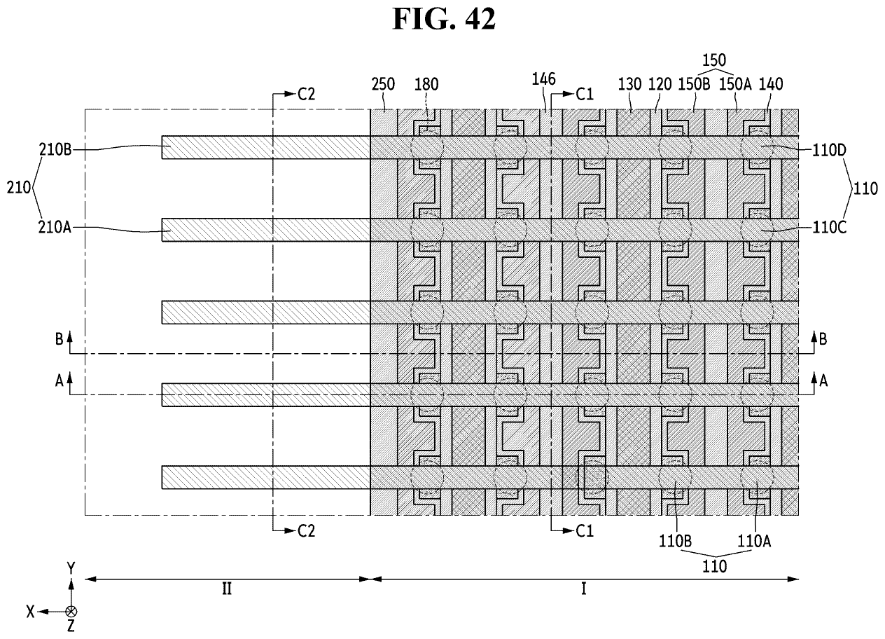

Referring to FIGS. 42 to 45, a portion of the shield conductive film 250 in the second region II is removed.

For example, a mask pattern MP may be formed on a portion of the shield conductive film 250 in the first region I. The mask pattern MP may not be formed in the second region II. That is, the mask pattern MP may not cover the second region II so as to expose the second region. The mask pattern MP may be, for example, a photoresist pattern or a hard mask. However, embodiments of the present disclosure are not limited thereto. Subsequently, an etching process may be performed on the shield conductive film 250 using the mask pattern MP as an etching mask. As the etching process is performed, the portion of the shield conductive film 250 in the second region II may be removed. In some embodiments, the etching process may include a metal etchback process. The etching process may be performed in-situ (e.g., a single etching process in a chamber without a vacuum break to the chamber).

During the etching process, a portion of the spacer film 245 in the second region II may be removed (e.g., the spacer film 245 in the second region II may be thinned by the etching process). For example, a portion of the spacer film 245 exposed as the portion of the shield conductive film 250 in the second region II is removed may be removed. Thus, the spacer film 245 including the first portion 245a in the first region I and the second portion 245b in the second region II may be formed.

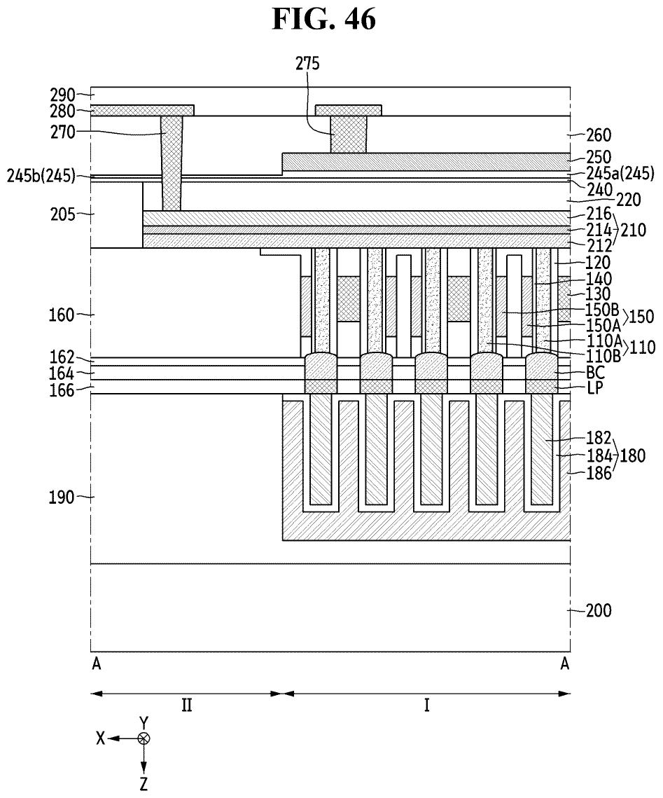

Referring to FIGS. 46 to 48, the filling insulating film 260, the first contact 270, the second contact 275, and the first wiring structure 280 are formed on the shield conductive film 250.

The filling insulating film 260 may be stacked on the shield conductive film 250 and the spacer film 245. The filling insulating film 260 may be disposed across the first region I and the second region II. For example, a portion of the filling insulating film 260 of the first region I may cover the shield conductive film 250, and a portion of the filling insulating film 260 of the second region II may cover the portion of the spacer film 245 of the second region II. Furthermore, a portion of the filling insulating film 260 of the second region II may be interposed between the conductive lines 210 of the second region II. For example, in the second region II, the filling insulating film 260 may fill at least a portion of the region between adjacent conductive lines 210, such as between the first conductive line 210A and second conductive line 210B.

The first contact 270 may extend through the filling insulating film 260, the spacer film 245, the liner film 240, and the capping film 220 so as to contact the lower surface of each conductive line 210. The second contact 275 may extend through the filling insulating film 260 so as to contact the lower surface of the shield conductive film 250.

The first wiring structure 280 may be formed on the filling insulating film 260. For example, the first inter-wiring insulating film 290 may be formed on the upper surface of the filling insulating film 260. The first wiring structure 280 may be formed within the first inter-wiring insulating film 290 to provide electrical paths connected to the gate electrodes 150, the back gate electrodes 130, the conductive lines 210, and/or the shield conductive film 250.

Next, referring to FIGS. 1 to 6, the carrier substrate 200 is removed. In this way, the semiconductor memory device as described above according to FIGS. 1 to 7A,7B, 7C, 7D and/or 7E may be manufactured.

In the semiconductor memory device, the conductive shield 250 may be inserted between the conductive lines to reduce coupling noise between the conductive lines 210 (e.g., bit lines). For example, the conductive shield that covers the conductive lines to fill at least a portion of the regions between the conductive lines may be provided. However, the conductive shield should be patterned so that at least part of the conductive lines are exposed with respect to the conductive shield. For example, in order to form a contact that contacts the conductive lines, the conductive shield may be patterned to not to cover the ends of the conductive lines and expose the same.

According to some embodiments, the method for manufacturing the semiconductor memory device may provide the patterned shield conductive film 250 via a relatively simple process step. For example, as described above, the shield conductive film 250 may be formed not to cover the second region II via only one-time (e.g., single) etching process (e.g., metal etching process) using the mask pattern MP. In this manner, the semiconductor memory device with improved performance and productivity and a method for manufacturing the same may be provided using a reduced number of process steps.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present invention. Therefore, it should be appreciated that the embodiments as described above are not restrictive but illustrative in all respects.

What is claimed is:

1. A semiconductor memory device comprising a first region and a second region arranged along a first direction, the semiconductor memory device comprising:
an active pattern in the first region;
a conductive line on a lower surface of the active pattern, the conductive line connected to the active pattern and extending in the first direction across the first region and the second region;
a spacer film extending along a side surface and a lower surface of the conductive line, the spacer film including a first portion in the first region and a second portion in the second region;
a shield conductive film extending below the first portion of the spacer film and not extending below the second portion of the spacer film;
a gate electrode adjacent to a side surface of the active pattern, the gate electrode extending in a second direction crossing the first direction; and
a data storage structure on an upper surface of the active pattern, the data storage structure connected to the active pattern,
wherein a thickness of the second portion of the spacer film is smaller than a thickness of the first portion of the spacer film, or the first portion of the spacer film extends along the lower surface of the conductive line and the second portion of the spacer film does not extend along the lower surface of the conductive line.

2. The semiconductor memory device of claim 1, wherein the conductive line has an end in the second region.

3. The semiconductor memory device of claim 1, further comprising a voltage source electrically connected to the shield conductive film to apply a ground voltage to the shield conductive film.

4. The semiconductor memory device of claim 1, further comprising:
a first contact in the first region, the first contact connected to a lower surface of the shield conductive film; and
a second contact in the second region, the second contact connected to the lower surface of the conductive line.

5. The semiconductor memory device of claim 1, wherein the first portion of the spacer film is formed on the lower surface of the conductive line and has a first thickness, and the second portion of the spacer film is formed on the lower surface of the conductive line and has a second thickness smaller than the first thickness.

6. The semiconductor memory device of claim 5, wherein the second portion of the spacer film is formed on the side surface of the conductive line and has a third thickness greater than the second thickness.

7. The semiconductor memory device of claim 1, wherein the first portion of the spacer film is formed on the side surface of the conductive line and has a first thickness, and the second portion of the spacer film is formed on the side surface of the conductive line and has a second thickness smaller than the first thickness.

8. The semiconductor memory device of claim 1, wherein further comprising a liner film interposed between the conductive line and the spacer film.

9. The semiconductor memory device of claim 1, wherein the shield conductive film includes a metal film or a metal nitride film.

10. The semiconductor memory device of claim 1, wherein the shield conductive film includes a void adjacent to the side surface of the conductive line.

11. The semiconductor memory device of claim 1, wherein the spacer film includes a silicon oxide film.

12. A semiconductor memory device comprising a first region and a second region arranged along a first direction, the semiconductor memory device comprising:
a first active pattern and a second active pattern in the first region, the first active pattern and the second active pattern spaced apart from each other in a second direction crossing the first direction;
a first conductive line on a lower surface of the first active pattern, the first conductive line connected to the first active pattern and extending in the first direction across the first region and the second region;
a second conductive line on a lower surface of the second active pattern, the second conductive line connected to the second active pattern and extending in the first direction across the first region and the second region;
a shield conductive film interposed between the first conductive line and the second conductive line in the first region;
a filling insulating film interposed between the first conductive line and the second conductive line in the second region;
a spacer film including:
a first portion in the first region that is interposed between the first conductive line and the shield conductive film; and
a second portion in the second region that is interposed between the first conductive line and the filling insulating film;
a gate electrode adjacent to a side surface of the first active pattern and adjacent to a side surface of the second active pattern, the gate electrode extending in the second direction; and
a first data storage structure on an upper surface of the first active pattern and connected to the first active pattern, and a second data storage structure on an upper surface of the second active pattern and connected to the second active pattern,
wherein a thickness of the second portion of the spacer film is smaller than a thickness of the first portion of the spacer film, or the first portion of the spacer film extends along lower surfaces of the first conductive line and the second conductive line and the second portion of the spacer film does not extend along the lower surfaces of the first conductive line and the second conductive line.

13. The semiconductor memory device of claim 12, wherein each of the first conductive line and the second conductive line has an end disposed in the second region.

14. The semiconductor memory device of claim 12, further comprising a voltage source electrically connected to the shield conductive film to apply a ground voltage to the shield conductive film.

15. The semiconductor memory device of claim 12, further comprising:
a first contact in the first region, the first contact connected to a lower surface of the shield conductive film; and
a second contact in the second region that is connected to the lower surface of the first conductive line.

16. The semiconductor memory device of claim 12, wherein the shield conductive film includes:
a filling conductive film at least partially filling a region between the first conductive line and the second conductive line and extending below the first conductive line and the second conductive line; and
a plate conductive film on a lower surface of the filling conductive film.

17. The semiconductor memory device of claim 16,
wherein the filling conductive film is a titanium nitride film, and
wherein the plate conductive film is a tungsten film.

18. A semiconductor memory device comprising a first region and a second region arranged along a first direction, the semiconductor memory device comprising:
an active pattern in the first region;
a conductive line on a lower surface of the active pattern, the conductive line connected to the active pattern, the conductive line extending in the first direction, and the conductive line having an end in the second region;
a capping film extending along a lower surface of the conductive line;
a spacer film extending along a side surface of the conductive line and a side surface and a lower surface of the capping film, the spacer film including a first portion in the first region and a second portion in the second region;
a shield conductive film extending below the first portion of the spacer film and not extending below the second portion of the spacer film;
a gate electrode adjacent to a side surface of the active pattern, the gate electrode extending in a second direction crossing the first direction;
a data storage structure on an upper surface of the active pattern, the data storage structure being connected to the active pattern;
a first contact in the first region, the first contact connected to a lower surface of the shield conductive film; and
a second contact in the second region, the second contact connected to the lower surface of the conductive line,
wherein the second portion of the spacer film extends along a lower surface of the capping film in the first region and does not extend along the lower surface of the capping film in the second region.

19. The semiconductor memory device of claim 18, wherein the shield conductive film extends below and contacts a lowermost surface of the spacer film.

20. The semiconductor memory device of claim 18, further comprising a voltage source electrically connected to the shield conductive film to apply a ground voltage to the shield conductive film.
